(19) United States
(12) Patent Application Publication
(10) Pub. No.: US 2025/0113681 A1
(43) Pub. Date: Apr. 3, 2025

(54) DISPLAY PANEL, METHOD FOR PREPARING THE DISPLAY PANEL AND DISPLAY DEVICE

(71) Applicant: Tianma Advanced Display Technology Institute (Xiamen) Co., Ltd., Xiamen (CN)

(72) Inventors: Finley KONG, Xiamen (CN); Kerui XI, Xiamen (CN); Bo ZHOU, Xiamen (CN); Jingfeng GUO, Xiamen (CN); Ying LIU, Xiamen (CN)

(73) Assignee: Tianma Advanced Display Technology Institute (Xiamen) Co., Ltd., Xiamen (CN)

(21) Appl. No.: 18/968,419

(22) Filed: Dec. 4, 2024

(30) Foreign Application Priority Data
Dec. 6, 2023 (CN) 202311668019.9
Aug. 7, 2024 (CN) 202411080260.4

(51) Int. Cl. H10H 29/01; H10H 29/24; H10H 29/49

(52) U.S. Cl. CPC H10H 29/012; H10H 29/24; H10H 29/49

(57) ABSTRACT

A display panel includes a first array substrate and multiple light-emitting elements. A light-emitting element includes a first binding electrode and a second binding electrode. The first array substrate includes multiple pixel disposition regions. A pixel disposition region includes a first pad and/or a second pad. The first binding electrode is electrically connected to the first pad, and the second binding electrode is electrically connected to the second pad. The area of the projection of the first pad on the plane on which the display panel is located is greater than or equal to N times the area of the projection of the first binding electrode on the plane, and/or the area of the projection of the second pad on the plane is greater than or equal to N times the area of the projection of the second binding electrode on the plane, where N≥2.

### CROSS-REFERENCE TO RELATED APPLICATIONS

This application claims priority to Chinese Patent Application No. 202411080260.4, filed on Aug. 7, 2024, and Chinese Patent Application No. 202311668019.9, filed on Dec. 6, 2023, the disclosures of which are incorporated herein by reference in their entireties.

### TECHNICAL FIELD

The present disclosure relates to the field of display technology and, in particular, to a display panel, a method for preparing the display panel and a display device.

### BACKGROUND

Light-emitting diode (LED) display has the advantages of self-luminescence, a low drive voltage, high luminescence efficiency, a fast response speed, high clarity and contrast and a wide operation temperature range. As a new generation of display technology, the LED display has entered the stage of time.

However, LEDs are generally small in size, especially for MicroLEDs and Mini LEDs which are micrometer-sized. If an LED in a display panel is damaged, it is difficult to repair.

### SUMMARY

The present disclosure provides a display panel, a method for preparing the display panel and a display device to reduce the repair difficulty of the display panel and improve the yield and display effect of the display panel.

According to an aspect of the present disclosure, a display panel is provided. The display panel includes a first array substrate and a plurality of light-emitting elements located on one side of the first array substrate. A light-emitting element of the plurality of light-emitting elements includes a first binding electrode and a second binding electrode.

The first array substrate includes a plurality of pixel disposition regions corresponding to the plurality of light-emitting elements respectively. A pixel disposition region of the plurality of pixel disposition regions includes a first pad and/or a second pad. The first binding electrode is electrically connected to the first pad; the second binding electrode is electrically connected to the second pad.

An area of a projection of the first pad on a plane on which the display panel is located is greater than or equal to N times an area of a projection of the first binding electrode on the plane on which the display panel is located, and/or an area of a projection of the second pad on the plane on which the display panel is located is greater than or equal to N times an area of a projection of the second binding electrode on the plane on which the display panel is located, where N≥2.

According to another aspect of the present disclosure, a method for preparing a display panel is provided and includes the steps below.

A first array substrate and a plurality of light-emitting elements are provided, where a light-emitting element of the plurality of light-emitting elements includes a first binding electrode and a second binding electrode, the first array substrate includes a plurality of pixel disposition regions corresponding to the plurality of light-emitting elements respectively, and a pixel disposition region of the plurality of pixel disposition regions includes a first pad and/or a second pad.

The plurality of light-emitting elements are transferred to the plurality of pixel disposition regions respectively to enable first binding electrodes to be bonded to first pads and second binding electrodes to be bonded to second pads, where an area of a projection of the first pad on a plane on which the display panel is located is greater than or equal to N times an area of a projection of the first binding electrode on the plane on which the display panel is located, and/or an area of a projection of the second pad on the plane on which the display panel is located is greater than or equal to N times an area of a projection of the second binding electrode on the plane on which the display panel is located, where N≥2.

According to yet another aspect of the present disclosure, a display device is provided. The display device includes the preceding display panel.

It is to be understood that the content described in this section is neither intended to identify key or critical features of the embodiments of the present disclosure nor intended to limit the scope of the present disclosure. Other features of the present disclosure become easily understood through the description provided hereinafter.

### BRIEF DESCRIPTION OF DRAWINGS

To illustrate technical solutions of embodiments of the present disclosure more clearly, drawings used in the description of the embodiments are briefly described hereinafter. Apparently, the drawings described hereinafter illustrate part of the embodiments of the present disclosure, and those of ordinary skill in the art may obtain other drawings based on the drawings described hereinafter on the premise that no creative work is done.

FIG. 1 is a diagram illustrating the structure of a repair process of a display panel in the related art.

FIG. 2 is another diagram illustrating the structure of a repair process of a display panel in the related art.

FIG. 3 is a top view of a display panel according to an embodiment of the present disclosure.

FIG. 4 is a cross-section view of a display panel in FIG. 3 taken along the section line F1-F1′.

FIG. 5 is another top view of a display panel according to an embodiment of the present disclosure.

FIG. 6 is a cross-section view of a display panel in FIG. 5 taken along the section line F2-F2′.

FIG. 7 is another top view of a display panel according to an embodiment of the present disclosure.

FIG. 8 is a cross-section view of a display panel in FIG. 7 taken along the section line F3-F3′.

FIG. 9 is another top view of a display panel according to an embodiment of the present disclosure.

FIG. 10 is a cross-section view of a display panel in FIG. 9 taken along the section line F4-F4′.

FIG. 11 is another cross-section view of a display panel in FIG. 5 taken along the section line F2-F2′.

FIG. 12 is a cross-section view of a display panel in FIG. 5 taken along the section line F102-F102′.

FIG. 13 is another cross-section view of a display panel in FIG. 5 taken along the section line F102-F102′.

FIG. 14 is another cross-section view of a display panel in FIG. 5 taken along the section line F2-F2′.

FIG. 15 is another cross-section view according to an embodiment of the present disclosure.

FIG. 16 is another cross-section view according to an embodiment of the present disclosure.

FIG. 17 is a top view of a first array substrate according to an embodiment of the present disclosure.

FIG. 18 is another top view of a first array substrate according to an embodiment of the present disclosure.

FIG. 19 is a partial top view of a display panel in FIG. 5.

FIG. 20 is a partial top view of a display panel in FIG. 7.

FIG. 21 is a cross-section view of a display panel in FIG. 3 taken along the section line F101-F101′.

FIG. 22 is another cross-section view of a display panel in FIG. 5 taken along the section line F102-F102′.

FIG. 23 is a cross-section view of a display panel in FIG. 9 taken along the section line F104-F104′.

FIG. 24 is a cross-section view of a first light-emitting element and a second light-emitting element according to an embodiment of the present disclosure.

FIG. 25 is another cross-section view of a first light-emitting element and a second light-emitting element according to an embodiment of the present disclosure.

FIG. 26 is another cross-section view of a first light-emitting element and a second light-emitting element according to an embodiment of the present disclosure.

FIG. 27 is a top view of a first light-emitting element and a second light-emitting element according to an embodiment of the present disclosure.

FIG. 28 is a top view of a display panel to which a first light-emitting element and a second light-emitting element in FIG. 27 are applied.

FIG. 29 is another top view of a first light-emitting element and a second light-emitting element according to an embodiment of the present disclosure.

FIG. 30 is a top view of a display panel to which a first light-emitting element and a second light-emitting element in FIG. 29 are applied.

FIG. 31 is another cross-section view of a first light-emitting element and a second light-emitting element according to an embodiment of the present disclosure.

FIG. 32 is another cross-section view of a first light-emitting element and a second light-emitting element according to an embodiment of the present disclosure.

FIG. 33 is another top view of a first light-emitting element and a second light-emitting element according to an embodiment of the present disclosure.

FIG. 34 is another top view of a first light-emitting element and a second light-emitting element according to an embodiment of the present disclosure.

FIG. 35 is another cross-section view of a first light-emitting element and a second light-emitting element according to an embodiment of the present disclosure.

FIG. 36 is another cross-section view of a display panel according to an embodiment of the present disclosure.

FIG. 37 is another cross-section view of a display panel according to an embodiment of the present disclosure.

FIG. 38 is another top view of a display panel according to an embodiment of the present disclosure.

FIG. 39 is another top view of a display panel according to an embodiment of the present disclosure.

FIG. 40 is a flowchart of a method for preparing a display panel according to an embodiment of the present disclosure.

FIG. 41 is another flowchart of a method for preparing a display panel according to an embodiment of the present disclosure.

FIG. 42 is a diagram illustrating structures in a process for preparing a display panel according to an embodiment of the present disclosure.

FIG. 43 is another diagram illustrating structures in a process for preparing a display panel according to an embodiment of the present disclosure.

FIG. 44 is another diagram illustrating structures in a process for preparing a display panel according to an embodiment of the present disclosure.

FIG. 45 is a diagram illustrating the structure of a display device according to an embodiment of the present disclosure.

### DETAILED DESCRIPTION

To make solutions of the present disclosure better understood by those skilled in the art, solutions of embodiments of the present disclosure are described hereinafter clearly and completely in conjunction with the drawings in embodiments of the present disclosure. Apparently, the embodiments described hereinafter are part, not all, of embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims and drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. In addition, terms “comprising”, “including” and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

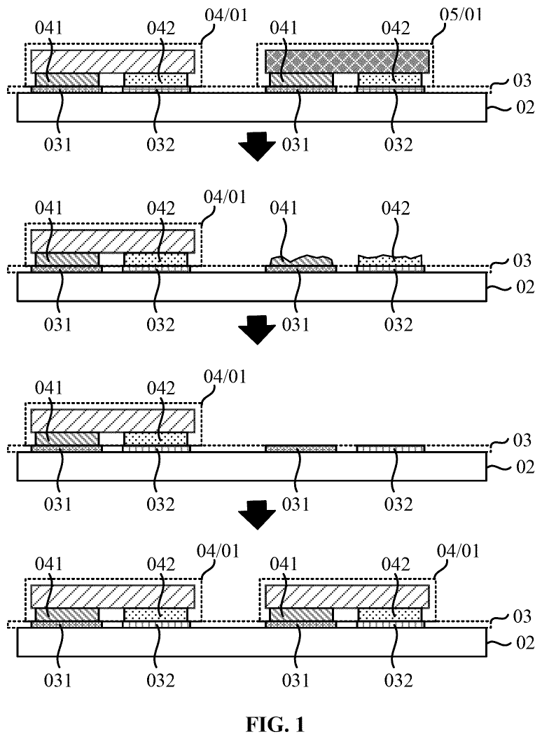

FIG. 1 is a diagram illustrating the structure of a repair process of a display panel in the related art. Referring to FIG. 1, the display panel includes an array substrate 02 and a conductive layer 03 located on the surface of one side of the array substrate 02. The conductive layer 03 includes first pads 031 and second pads 032. Surfaces of the first pads 031 are provided with first eutectic layers, and surfaces of the second pads 032 are provided with second eutectic layers (the first eutectic layers and the second eutectic layers are not shown in the figure). First binding electrodes 041 of light-emitting elements 01 are bonded to the first pads 031 through the first eutectic layers, and second binding electrodes 042 of the light-emitting elements 01 are bonded to the second pads 032 through the second eutectic layers. If a light-emitting element 05 among the light-emitting elements 01 is damaged and cannot emit light normally, the light-emitting element 05 requires removal; the removal of the damaged light-emitting element 05 may cause a first eutectic layer and/or a second eutectic layer to be damaged or incomplete or may also leave part of a first binding electrode 041 on a first pad 031 and/or part of a second binding electrode 042 on a second pad 032, as shown in FIG. 1. Before a light-emitting element 04 that is outside the display panel and can emit light normally is transferred to the original position of the light-emitting element 05, the first eutectic layer and/or the second eutectic layer require repair, or the residual first binding electrode 041 and/or the residual second binding electrode 042 require removal, and the first eutectic layer and/or the second eutectic layer are repaired after the residual binding electrodes are removed. Subsequently, the light-emitting element 04 that is outside the display panel and can emit light normally is transferred to the original position of the light-emitting element 05, a first binding electrode 041 of the light-emitting element 04 is bonded to the first pad 031 through the repaired first eutectic layer, and a second binding electrode 042 of the light-emitting element 04 is bonded to the second pad 032 through the repaired second eutectic layer. A method for repairing the display panel is to perform in-situ repair in the position of the abnormal light-emitting element 05, which requires removing the residual binding electrodes on the pads and performing eutectic layer repair on the pads where the residual binding electrodes are removed. The repair method has a complex process and large repair difficulty.

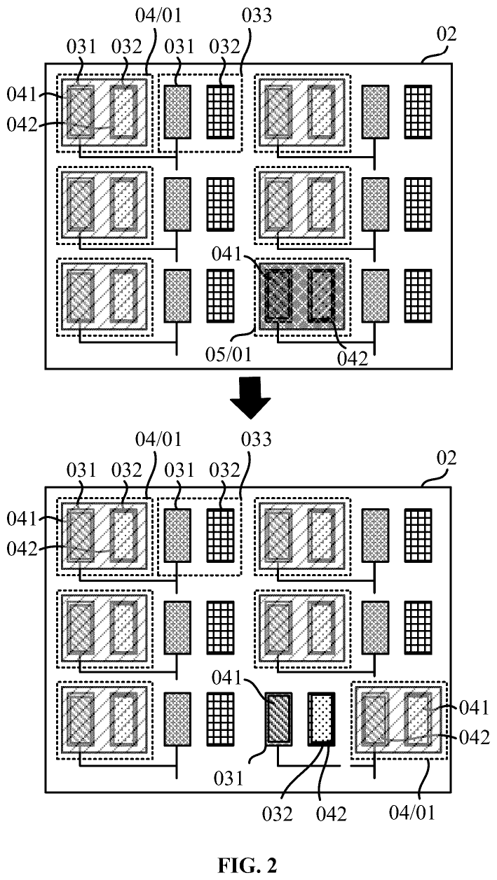

FIG. 2 is another diagram illustrating the structure of a repair process of a display panel in the related art. Referring to FIG. 2, a redundant pad group 033 is disposed next to each light-emitting element 01, that is, the each light-emitting element 01 is provided with a redundant light-emitting element disposition region. The redundant pad group 033 includes a first pad 031 and a second pad 032. The surface of the first pad 031 of the redundant pad group 033 is also provided with a first eutectic layer, and the surface of the second pad 032 of the redundant pad group 033 is also provided with a second eutectic layer (the first eutectic layer and the second eutectic layer are not shown in the figure). A first pad 031 bonded to a first binding electrode 041 of the each light-emitting element 01 and the first pad 031 of the redundant pad group 033 are electrically connected to the same one pixel driving circuit, and a second pad 032 bonded to a second binding electrode 042 of the each light-emitting element 01 and the second pad 032 of the redundant pad group 033 are electrically connected to a common electrode (the pixel driving circuit and the common electrode are not shown in the figure). If the light-emitting element 05 among the light-emitting elements 01 cannot emit light normally, the light-emitting element 05 requires removal, but the residual part of the first binding electrode 041 and/or the residual part of the second binding electrode 042 do not need removing, the first eutectic layer of the first pad 031 and/or the second eutectic layer of the second pad 032 do not need repairing, and the light-emitting element 04 that can emit light normally may be directly transferred to the redundant light-emitting element disposition region. The first binding electrode 041 of the light-emitting element 04 is bonded to the first pad 031 of the redundant pad group 033 through the first eutectic layer, and the second binding electrode 042 of the light-emitting element 04 is bonded to the second pad 032 of the redundant pad group 033 through the second eutectic layer. Moreover, during the repair process, a connection line between the first pad 031 with the residual part of the first binding electrode 041 and the pixel driving circuit requires to be disconnected by laser to avoid problems such as line short circuits and abnormal grounding due to wrong connections between the first pad 031 with the residual part of the first binding electrode 041 and other conductive structures.

A method for repairing the display panel in FIG. 2 is to dispose redundant pad groups 033 on the array substrate. When the light-emitting element 05 cannot emit light normally, the light-emitting element 05 may be removed directly, and the light-emitting element 04 that can emit light normally is replaced in a redundant light-emitting element disposition region next to the light-emitting element 05. The replaced light-emitting element 04 is bonded to the first pad 031 of the redundant pad group 033 and the second pad 032 of the redundant pad group 033. Although the method for repairing a display panel can avoid the in-situ repair at the position of the abnormal light-emitting element 05 to reduce the process complexity and the repair difficulty of the display panel, the arrangement of the redundant pad groups 033 occupies the space of the light-emitting elements 01, which reduces the resolution of the display panel and does not facilitate the display effect of the display panel. Moreover, the connection line between the first pad 031 with the residual part of the first binding electrode 041 and the pixel driving circuit requires to be disconnected by laser, which has a complex process and repair difficulty to some extent.

To solve the preceding technical problems, embodiments of the present disclosure provide a display panel. The display panel includes a first array substrate and multiple light-emitting elements located on one side of the first array substrate. A light-emitting element includes a first binding electrode and a second binding electrode. The first array substrate includes multiple pixel disposition regions corresponding to the multiple light-emitting elements respectively. A pixel disposition region includes a first pad and/or a second pad. The first binding electrode is electrically connected to the first pad, and the second binding electrode is electrically connected to the second pad. The area of the projection of the first pad on the plane on which the display panel is located is greater than or equal to N times the area of the projection of the first binding electrode on the plane on which the display panel is located, and/or the area of the projection of the second pad on the plane on which the display panel is located is greater than or equal to N times the area of the projection of the second binding electrode on the plane on which the display panel is located, where N≥2.

With the preceding technical solutions adopted, for one aspect, the alignment difficulty of the light-emitting element can be reduced, and the binding yield can be improved; for another aspect, when a light-emitting element is damaged, after the damaged light-emitting element is removed, the first pad and the second pad do not need repairing, a light-emitting element for repair can be directly placed at the position of the originally damaged light-emitting element, and binding electrodes of the light-emitting element for repair are bonded to other regions of the pads where the binding electrodes are not bonded so that the repair difficulty can be reduced effectively. Moreover, during repair, the light-emitting element for repair can be placed at the position of the originally damaged light-emitting element for replacement, without disposing a redundant pad and a redundant pixel disposition region so that the impact on the resolution can be reduced effectively, thereby facilitating the improvement in the yield and display effect of the display panel.

The preceding is a core idea of the present disclosure. Based on the embodiments of the present disclosure, all other embodiments obtained by those of ordinary skill in the art are within the scope of the present disclosure on the premise that no creative work is done. Technical solutions of the embodiments of the present disclosure are described clearly and completely hereinafter in conjunction with the drawings in the embodiments of the present disclosure.

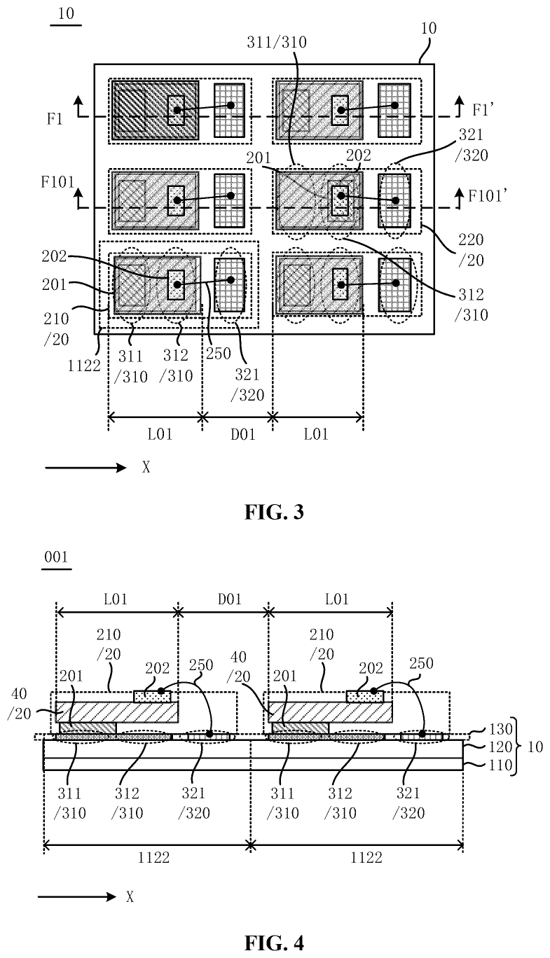

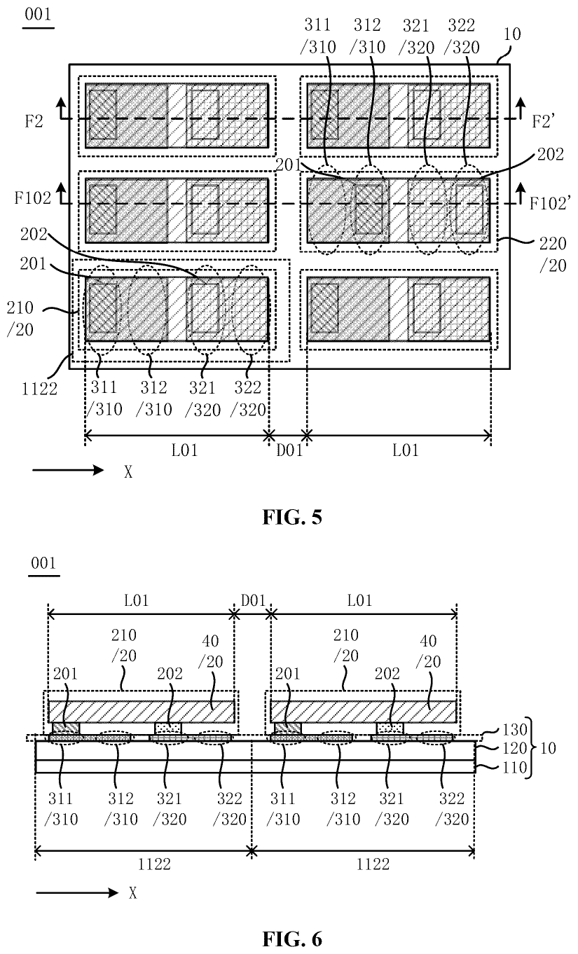

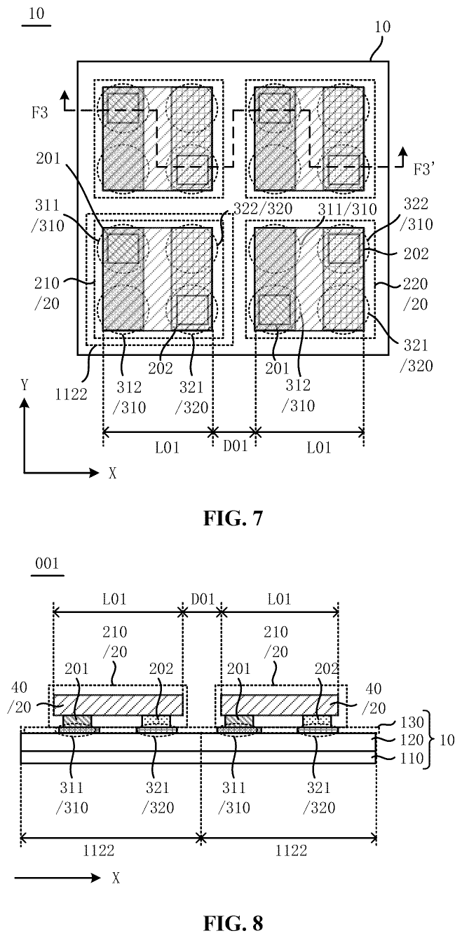

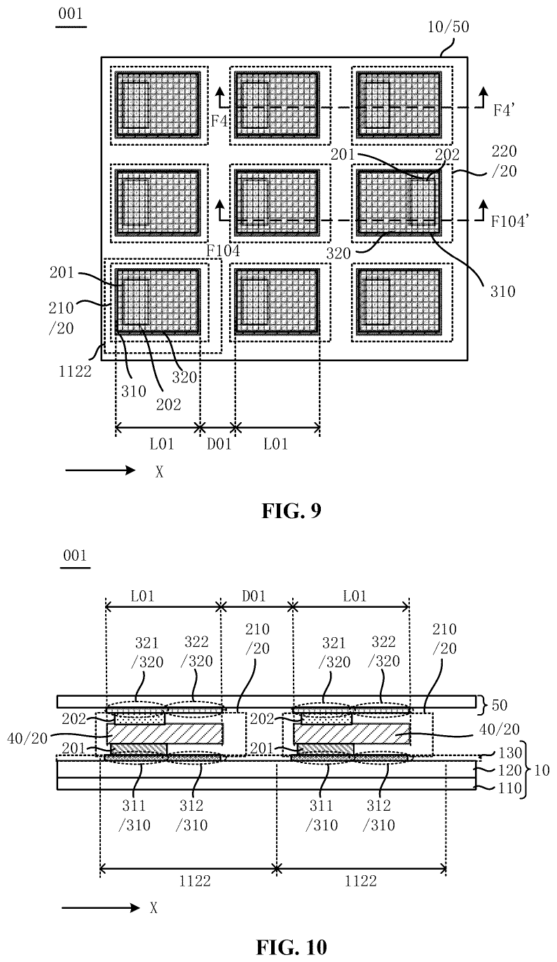

FIG. 3 is a top view of a display panel according to an embodiment of the present disclosure. FIG. 4 is a cross-section view of a display panel in FIG. 3 taken along the section line F1-F1′. FIG. 5 is another top view of a display panel according to an embodiment of the present disclosure. FIG. 6 is a cross-section view of a display panel in FIG. 5 taken along the section line F2-F2′. FIG. 7 is another top view of a display panel according to an embodiment of the present disclosure. FIG. 8 is a cross-section view of a display panel in FIG. 7 taken along the section line F3-F3′. FIG. 9 is another top view of a display panel according to an embodiment of the present disclosure. FIG. 10 is a cross-section view of a display panel in FIG. 9 taken along the section line F4-F4′. Referring to FIGS. 3 to 10, the display panel 001 includes a first array substrate 10 and multiple light-emitting elements 20 located on one side of the first array substrate 10. A light-emitting element 20 includes a first binding electrode 201 and a second binding electrode 202. The first array substrate 10 includes multiple pixel disposition regions 1122 corresponding to the multiple light-emitting elements 20 respectively. A pixel disposition region 1122 includes a first pad 310 and/or a second pad 320. The first binding electrode 201 is electrically connected to the first pad 310, and the second binding electrode 202 is electrically connected to the second pad 320. The area of the projection of the first pad 310 on the plane on which the first array substrate 10 is located is greater than or equal to N times the area of the projection of the first binding electrode 201 on the plane on which the first array substrate 10 is located, and/or the area of the projection of the second pad 320 on the plane on which the first array substrate 10 is located is greater than or equal to N times the area of the projection of the second binding electrode 202 on the plane on which the first array substrate 10 is located, where N≥2.

Exemplarily, the first array substrate 10 includes a base substrate 110, a circuit layer 120 and a conductive layer 130 located on the surface of one side of the circuit layer 120 facing away from the base substrate 110. The conductive layer 130 includes first pads 310 and/or second pads 320. The base substrate 110 may be a rigid substrate or a flexible substrate, which is not specifically limited in this embodiment. The material of the rigid substrate may include, but is not limited to, glass or silicon. The material of the flexible substrate may include, but is not limited to, polyimide (PI), polyethylene terephthalate (PET), or poly(methyl methacrylate) (PMMA). The circuit layer 120 includes pixel driving circuits (which are not shown in the figures). The pixel driving circuits are electrically connected to the first pads 310 of the conductive layer 130 or the second pads 320 of the conductive layer 130. The pixel driving circuits are electrically connected to the multiple light-emitting elements 20 through the first pads 310 or the second pads 320 and can drive the multiple light-emitting elements 20 to emit light.

The light-emitting element 20 includes a light-emitting structure 40. The light-emitting structure 40 includes a P-type conductive layer and an N-type conductive layer (which are not shown in the figures). One of the P-type conductive layer or the N-type conductive layer is electrically connected to the first binding electrode 201 of the light-emitting element 20, and the other one of the P-type conductive layer or the N-type conductive layer is electrically connected to the second binding electrode 202 of the light-emitting element 20. The light-emitting element 20 includes a perpendicular structure and an inverted structure. When the light-emitting element 20 is the perpendicular structure, the first binding electrode 201 and the second binding electrode 202 are located on two opposite sides of the light-emitting structure 40 respectively, and an electrode located on one side of the light-emitting structure 40 facing the first array substrate 10 may be bonded to a pad on the first array substrate 10; an electrode located on one side of the light-emitting structure 40 facing away from the first array substrate 10 may be electrically connected to another pad on the first array substrate 10 through a lead or may also be bonded to a pad on another substrate. When the light-emitting element 20 is the inverted structure, the first binding electrode 201 and the second binding electrode 202 are located on the same side of the light-emitting structure 40 and one side of the light-emitting structure 40 facing the first array substrate 10. In this case, the first binding electrode 201 and the second binding electrode 202 may be bonded to the first pad 310 and the second pad 320 respectively. In an embodiment, the surface of the first pad 310 is provided with a first eutectic layer, the surface of the second pad 320 is provided with a second eutectic layer (which is not shown in the figures), the first binding electrode 201 can be bonded to the first pad 310 through the first eutectic layer, and/or the second binding electrode 202 can be bonded to the second pad 320 through the second eutectic layer.

In an optional embodiment, the light-emitting element 20 is the perpendicular structure, the first array substrate 10 includes the first pad 310 and the second pad 320, the first binding electrode 201 of the light-emitting element 20 is bonded to the first pad 310, and the second binding electrode 202 of the light-emitting element 20 may be electrically connected to the second pad 320 through a lead 250, as shown in FIGS. 3 and 4. In another optional embodiment, the light-emitting element 20 is the inverted structure, the first array substrate 10 includes the first pad 310 and the second pad 320, the first binding electrode 201 of the light-emitting element 20 is bonded to the first pad 310, and the second binding electrode 202 of the light-emitting element 20 may be bonded to the second pad 320, as shown in FIGS. 5 to 8. In another optional embodiment, the light-emitting element 20 is the perpendicular structure, the display panel 001 further includes a second substrate 50, the first array substrate 10 includes the first pad 310, and the second substrate 50 includes the second pad 320, or the first array substrate 10 may include the second pad 320, the second substrate 50 includes the first pad 310, the light-emitting element 20 is located between the first array substrate 10 and the second substrate 50, the first binding electrode 201 of the light-emitting element 20 is bonded to the first pad 310, and the second binding electrode 202 of the light-emitting element 20 is bonded to the second pad 320, as shown in FIGS. 9 and 10. The light-emitting element 20 may be an LED with a large size, a Mini LED with a small size, or a MicroLED with a small size, which is not limited in the embodiments of the present disclosure.

In an embodiment, compared with the area of the projection of the first binding electrode 201 on the plane on which the display panel 001 is located, the area of the projection of the first pad 310 on the plane on which the display panel 001 is located is larger and may be two or more than two times the area of the projection of the first binding electrode 201 on the plane on which the display panel 001 is located so that the first binding electrode 201 of the light-emitting element 20 can be bonded in different regions in the first pad 310 separately, and the different regions do not overlap with each other; and/or compared with the area of the projection of the second binding electrode 202 on the plane on which the display panel 001 is located, the area of the projection of the second pad 320 on the plane on which the display panel 001 is located is larger and may be two or more than two times the area of the projection of the second binding electrode 202 on the plane on which the display panel 001 is located so that the second binding electrode 202 of the light-emitting element 20 can be bonded in different regions in the second pad 320 separately, and the different regions do not overlap with each other. When existing, the damaged light-emitting element 20 may be directly removed, the first binding electrode 201 left on the first pad 310 and/or the second binding electrode 202 left on the second pad 320 do not need removing, and the first eutectic layer on the surface of the first pad 310 and/or the second eutectic layer on the surface of the second pad 320 do not need repairing. In an embodiment, a light-emitting element 20 for repair may be directly placed at the position of the originally damaged light-emitting element 20, a first binding electrode 201 of the light-emitting element 20 for repair is bonded in other regions on the first pad 310 where the electrode is not left and the first eutectic layer is not damaged, and/or a second binding electrode 202 of the light-emitting element 20 for repair is bonded in other regions on the second pad 320 where the electrode is not left and the second eutectic layer is not damaged.

In the case where the binding electrodes left on the pads do not need removing, and the eutectic layers do not need repairing, repair opportunities for the light-emitting element 20 in the pixel disposition region 1122 are limited. The repair opportunities for the light-emitting element 20 in the pixel disposition region 1122 are related to the multiple value N of the area of the projection of the first pad 310 on the plane on which the first array substrate 10 is located and the area of the projection of the first binding electrode 201 on the plane on which the first array substrate 10 is located and/or the multiple value N of the area of the projection of the second pad 320 on the plane on which the first array substrate 10 is located and the area of the projection of the second binding electrode 202 on the plane on which the first array substrate 10 is located. Generally, the larger N is, the more repair opportunities there are. Moreover, the larger N is, the larger the areas of the projections of the pads on the plane on which the display panel 001 is located are compared with the areas of the projections of the binding electrodes on the plane on which the display panel 001 is located, the lower the alignment difficulties of the binding electrodes of the light-emitting element 20 are, and the higher the alignment bonding yield is.

In addition, if the light-emitting element 20 in the pixel disposition region 1122 still needs to be repaired after the number of times of repair reaches the upper limit of the preceding repair opportunities, the binding electrodes left on the pads may be first removed, the eutectic layers on the surfaces of the pads are repaired, and the light-emitting element 20 for repair is then placed at the position of the originally damaged light-emitting element 20. Since the areas of the projections of the binding electrodes on the plane on which the display panel 001 is located are small compared with the areas of the projections of the pads on the plane on which the display panel 001 is located, during the process of removing the binding electrodes left on the pads and/or repairing the eutectic layers on the surfaces of the pads, the areas required for operation are also small, and there is no need to perform large area operations on the surfaces of the entire pads so that the repair difficulty can also be reduced to some extent, thereby facilitating the improvement in the repair efficiency.

With continued reference to FIGS. 3 to 10, the pixel disposition region 1122 includes one first pad 310 and/or one second pad 320, and one pixel disposition region 1122 includes one light-emitting element 20. A redundant pad and a redundant pixel disposition region are not necessarily disposed for the light-emitting element 20 in the display panel 001, thereby facilitating the improvement in the resolution of the display panel 001. For example, the area of the projection of the first pad 310 of the first array substrate 10 on the plane on which the display panel 001 is located and/or the area of the projection of the second pad 320 of the first array substrate 10 on the plane on which the display panel 001 is located may be increased appropriately while the projection of the size of the first binding electrode 201 of the light-emitting element 20 on the plane on which the display panel 001 is located and/or the projection of the size of the second binding electrode 202 of the light-emitting element 20 on the plane on which the display panel 001 is located are reduced appropriately to enable the area of the projection of the first pad 310 on the plane on which the first array substrate 10 is located to be greater than or equal to N times the area of the projection of the first binding electrode 201 on the plane on which the first array substrate 10 is located and/or enable the area of the projection of the second pad 320 on the plane on which the first array substrate 10 is located to be greater than or equal to N times the area of the projection of the second binding electrode 202 on the plane on which the first array substrate 10 is located so that the impact on the size of the pixel disposition region can be reduced, thereby improving the resolution of the display panel 001.

In the display panel provided in the embodiments of the present disclosure, the areas of the projections of the pads on the plane on which the display panel is located are large, and/or the areas of the projections of the binding electrodes on the plane on which the display panel is located are small so that the area of the projection of the first pad on the plane on which the display panel is located can be two or more than two times the area of the projection of the first binding electrode on the plane on which the display panel is located, and/or the area of the projection of the second pad on the panel on which the display panel is located can be two or more than two time the area of the second binding electrode on the plane on which the display panel is located. For one aspect, the alignment difficulty of the light-emitting element can be reduced, and the binding yield can be improved; for another aspect, when a light-emitting element is damaged, after the damaged light-emitting element is removed, the first pad and the second pad do not need repairing, a light-emitting element for repair can be directly placed within a pixel disposition region in which the originally damaged light-emitting element is located, and binding electrodes of the light-emitting element for repair are bonded to other regions of the pads where the binding electrodes are not bonded so that the repair difficulty can be reduced effectively. Moreover, during repair, the light-emitting element for repair can be placed at the position of the originally damaged light-emitting element for replacement, without disposing a redundant pad and a redundant pixel disposition region so that the impact on the resolution can be reduced effectively, thereby facilitating the improvement in the yield and display effect of the display panel.

In an optional embodiment, with continued reference to FIGS. 3 to 10, the projection of the light-emitting element 20 on the plane on which the display panel 001 is located covers the projection of the first pad 310 on the plane on which the display panel 001 is located and/or the projection of the second pad 320 on the plane on which the display panel 001 is located and covers at least one pad in the pixel disposition region 1122 so that the spacing between adjacent light-emitting elements 20 can be reduced, and the proportion of the light-emitting element 20 in a display region of the display panel 001 can be increased. In this manner, while the area of the first pad 310 and/or the area of the second pad 320 are increased so that the repair difficulty can be reduced, and the impact on the resolution can be reduced, thereby facilitating the improvement in the resolution of the display panel 001. In an embodiment, the spacing D01 between two adjacent light-emitting elements 20 arranged in the first direction X is less than the length L01 of the light-emitting element 20 in the first direction X, and the first direction X is parallel to the plane on which the display panel 001 is located.

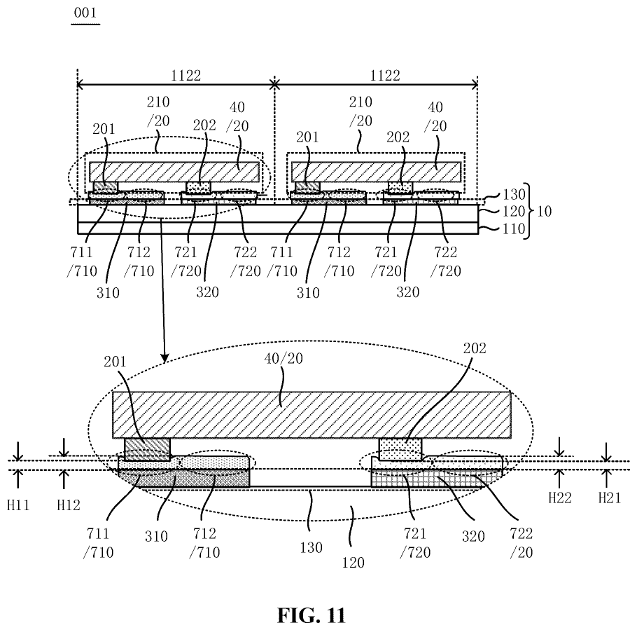

Optionally, FIG. 11 is another cross-section view of a display panel in FIG. 5 taken along the section line F2-F2′. Referring to FIG. 11, the first array substrate 10 further includes first connection electrodes 710 and/or second connection electrodes 720. A first connection electrode 710 is located between the first binding electrode 201 and the first pad 310, and a second connection electrode 720 is located between the second binding electrode 202 and the second pad 320. The first connection electrode 710 includes a first eutectic portion 711 and a first connection portion 712, and/or the second connection electrode 720 includes a second eutectic portion 721 and a second connection portion 722. The projection of the first eutectic portion 711 on the plane on which the display panel 001 is located overlaps the projection of the first binding electrode 201 on the plane on which the display panel 001 is located, and the projection of the first connection portion 712 on the plane on which the display panel 001 is located does not overlap the projection of the first binding electrode 201 on the plane on which the display panel 001 is located; and/or the projection of the second eutectic portion 721 on the plane on which the display panel 001 is located overlaps the projection of the second binding electrode 202 on the plane on which the display panel 001 is located, and the projection of the second connection portion 722 on the plane on which the display panel 001 is located does not overlap the projection of the second binding electrode 202 on the plane on which the display panel 001 is located.

With continued reference to FIG. 11, the thickness of the first eutectic portion 711 in the perpendicular direction of the plane on which the display panel 001 is located is the first eutectic thickness H11, the thickness of the first connection portion 712 in the perpendicular direction of the plane on which the display panel 001 is located is the first connection thickness H12, the thickness of the second eutectic portion 721 in the perpendicular direction of the plane on which the display panel 001 is located is the second eutectic thickness H21, and the thickness of the second connection portion 722 in the perpendicular direction of the plane on which the display panel 001 is located is the second connection thickness H22. Among at least some pixel disposition regions 1122, in the same one pixel disposition region 1122, the first connection thickness H12 is greater than or equal to the first eutectic thickness H11, and/or the second connection thickness H22 is greater than or equal to the second eutectic thickness H21.

Exemplarily, the light-emitting element 20 being the inverted structure and the first array substrate 10 including the first pad 310 and the second pad 320 is used as an example. When the light-emitting element 20 is transferred to the pixel disposition region 1122 of the first array substrate 10, the first connection electrode 710 and the second connection electrode 720 that are in the pixel disposition region 1122 are in a molten state, the first binding electrode 201 of the light-emitting element 20 contacts the first connection electrode 710, and the second binding electrode 202 of the light-emitting element 20 contacts the second connection electrode 720. A portion of the first connection electrode 710 that contacts the first binding electrode 201 is the first eutectic portion 711. A portion of the first connection electrode 710 that does not contact the first binding electrode 201 is the first connection portion 712. A portion of the second connection electrode 720 that contacts the second binding electrode 202 is the second eutectic portion 721. A portion of the second connection electrode 720 that does not contact the second binding electrode 202 is the second connection portion 722. In an embodiment, the projection of the first eutectic portion 711 on the plane on which the display panel 001 is located coincides with the projection of the first binding electrode 201 on the plane on which the display panel 001 is located, and the projection of the second eutectic portion 721 on the plane on which the display panel 001 is located coincides with the projection of the second binding electrode 202 on the plane on which the display panel 001 is located. An external force is applied to the light-emitting element 20, or the gravity of the light-emitting element 20 is used to cause the first binding electrode 201 of the light-emitting element 20 and the second binding electrode 202 of the light-emitting element 20 to press against the first eutectic portion 711 and the second eutectic portion 721 respectively so that the first eutectic portion 711 and the second eutectic portion 721 can have a smaller thickness, the first eutectic portion 711 can be connected to the first binding electrode 201, and the second eutectic portion 721 can be connected to the second binding electrode 202. The first binding electrode 201 is bonded to the first pad 310 through the first eutectic portion 711, and the second binding electrode 202 is bonded to the second pad 320 through the second eutectic portion 721 so that the light-emitting element 20 can be firmly secured to the first array substrate 10, and a driving current of the first array substrate 10 can be transmitted to the light-emitting element 20 to drive the light-emitting element 20 to emit light.

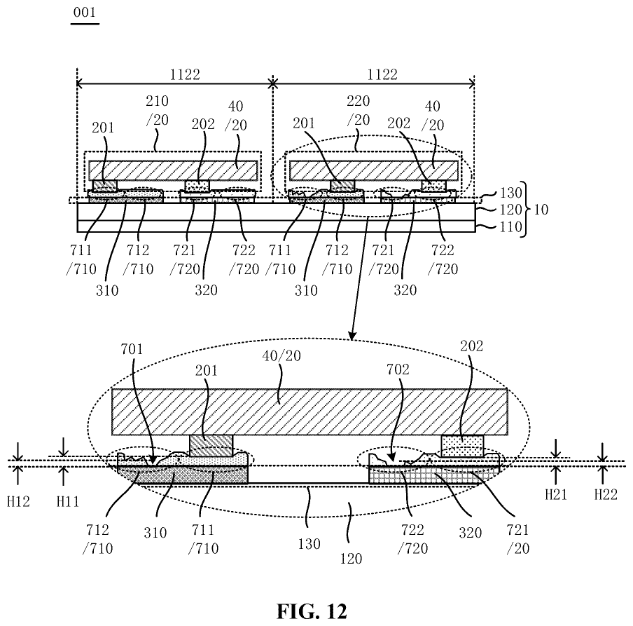

Based on the preceding embodiments, FIG. 12 is a cross-section view of a display panel in FIG. 5 taken along the section line F102-F102′. Referring to FIG. 12, the light-emitting element 20 being the inverted structure and the first array substrate 10 including the first pad 310 and the second pad 320 is used as an example. If present, the damaged light-emitting element 20 needs to be removed. When the damaged light-emitting element 20 is removed, the binding electrodes of the damaged light-emitting element 20 may take part of the first eutectic portion 711 and part of the second eutectic portion 721 away so that the original first eutectic portion 711 and the original second eutectic portion 721 may be damaged, and the thickness of some regions may be reduced. After the damaged light-emitting element 20 is removed, the light-emitting element 20 for repair is transferred to the position of the originally damaged light-emitting element 20, the first binding electrode 201 is connected to a region of the first connection electrode 710 that is not connected to a binding electrode, the second binding electrode 202 is connected to a region of the second connection electrode 720 that is not connected to a binding electrode, the first connection electrode 710 located under the first binding electrode 201 is a new first eutectic portion 711, the second connection electrode 720 located under the second binding electrode 202 is a new second eutectic portion 721, and the original first eutectic portion 711 and the original second eutectic portion 721 are the first connection portion 712 and the second connection portion 722 respectively. In this case, among the some pixel disposition regions 1122, the first connection thickness H12 of part of the first connection portion 712 is less than the first eutectic thickness H11 of the first eutectic portion 711, and/or in the same one pixel disposition region 1122, the second connection thickness H22 of part of the second connection portion 722 is less than the second eutectic thickness H21 of the second eutectic portion 721.

With continued reference to FIG. 12, among the some pixel disposition regions 1122, when the damaged light-emitting element 20 is removed, the binding electrodes of the damaged light-emitting element 20 may take much of the first eutectic portion 711 and/or much of the second eutectic portion 721 away so that the thickness of the first connection electrode 710 can be 0, and part of the first pad 310 can be exposed; and/or the thickness of the second connection electrode 720 can be 0, and part of the second pad 320 can be exposed. After the light-emitting element 20 for repair is transferred to the position of the originally damaged light-emitting element 20, the first connection electrode 710 located under the first binding electrode 201 is the new first eutectic portion 711, the second connection electrode 720 located under the second binding electrode 202 is the new second eutectic portion 721, and the original first eutectic portion 711 and the original second eutectic portion 721 are the first connection portion 712 and the second connection portion 722 respectively. In this case, among the some pixel disposition regions 1122, the first connection portion 712 includes a first hollow portion 701, and/or the second connection portion 722 includes a second hollow portion 702. In an optional embodiment, in the same one pixel disposition region 1122, the projection of the first hollow portion 701 on the plane on which the display panel 001 is located and/or the projection of the second hollow portion 702 on the plane on which the display panel 001 is located overlap the projection of the light-emitting element 20 on the plane on which the display panel is located so that at least part of the projection of the repaired light-emitting element 20 on the plane on which the display panel 001 is located can be located within the projection of the damaged light-emitting element 20 on the plane on which the display panel 001 is located, thereby facilitating the reduction in the impact of repairing the display panel 001 on the resolution and improving the display effect.

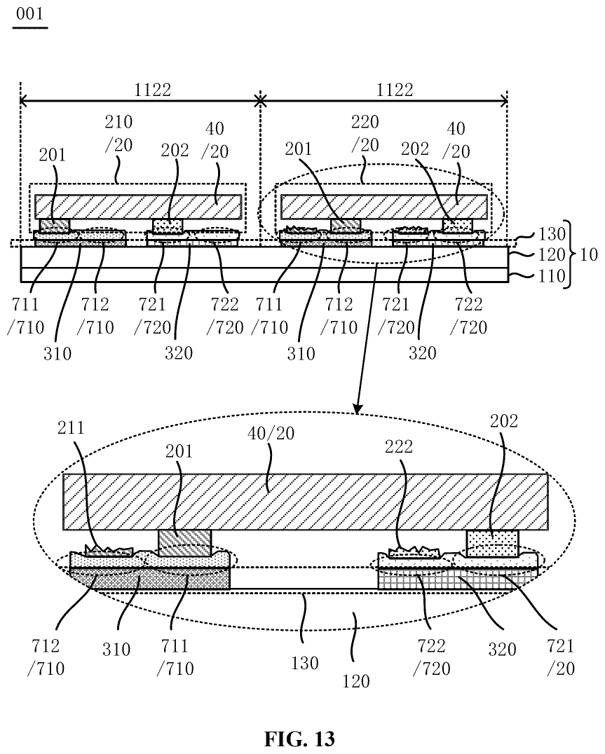

Based on the preceding embodiments, FIG. 13 is another cross-section view of a display panel in FIG. 5 taken along the section line F102-F102′. Referring to FIG. 13, the light-emitting element 20 being the inverted structure and the first array substrate 10 including the first pad 310 and the second pad 320 is used as an example. Among the some pixel disposition regions 1122, when the damaged light-emitting element 20 is removed, the binding electrodes of the damaged light-emitting element 20 may be left on the first array substrate 10 to form residual electrodes. After the light-emitting element 20 for repair is transferred to the position of the originally damaged light-emitting element 20, the first binding electrode 201 of the light-emitting element 20 for repair and the second binding electrode 202 of the light-emitting element 20 for repair can avoid the residual electrodes and be connected to a region of the first connection electrode 710 in which no binding electrode is left and a region of the second connection electrode 720 in which no binding electrode is left respectively. In this case, the some pixel disposition regions 1122 each include a first residual electrode 211 and/or a second residual electrode 222. The projection of the first residual electrode 211 on the plane on which the display panel 001 is located overlaps the projection of the first connection portion 712 on the plane on which the display panel 001 is located, and/or the projection of the second residual electrode 222 on the plane on which the display panel 001 is located overlaps the projection of the second connection portion 722 on the plane on which the display panel 001 is located, that is, in the same one pixel disposition region 1122, both the first residual electrode 211 and the second residual electrode 222 do not overlap the first eutectic portion 711, thereby ensuring that the first residual electrode 211 does not overlap the first binding electrode 201, and the second residual electrode 222 does not overlap the second binding electrode 202. In an optional embodiment, in the same one pixel disposition region 1122, the projection of the first residual electrode 211 on the plane on which the display panel 001 is located and/or the projection of the second residual electrode 222 on the plane on which the display panel 001 is located overlap the projection of the light-emitting element 20 on the plane on which the display panel is located so that the at least part of the projection of the repaired light-emitting element 20 on the plane on which the display panel 001 is located can be located within the projection of the damaged light-emitting element 20 on the plane on which the display panel 001 is located, thereby facilitating the reduction in the impact of repairing the display panel 001 on the resolution and improving the display effect.

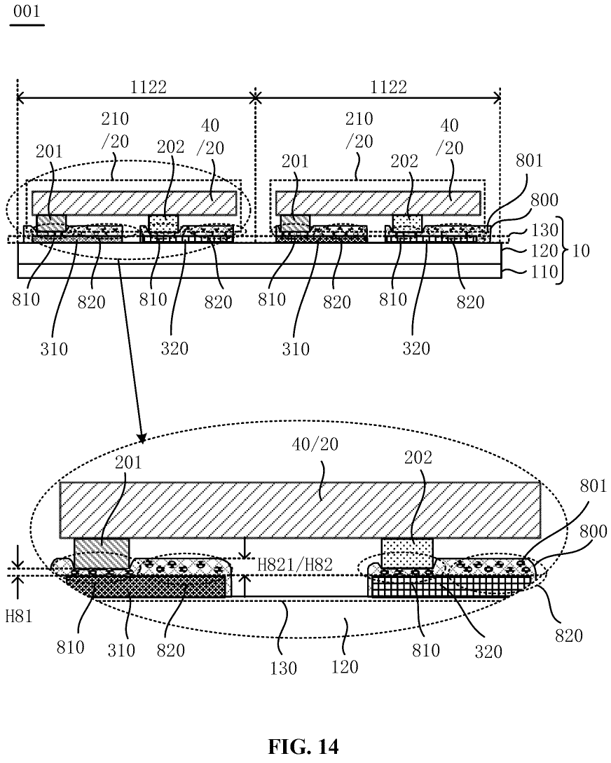

Optionally, FIG. 14 is another cross-section view of a display panel in FIG. 5 taken along the section line F2-F2′. Referring to FIG. 14, the display panel 001 further includes an adhesive layer 800. The adhesive layer 800 includes an adhesive and conductive particles 801. The adhesive layer 800 is located between the light-emitting element 20 and the first array substrate 10. The adhesive layer 800 includes multiple first adhesive portions 810 and at least one second adhesive portion 820. The projection of a first adhesive portion 810 on the plane on which the display panel 001 is located overlaps the projection of the first binding electrode 201 on the plane on which the display panel 001 is located or the projection of the second binding electrode 202 on the plane on which the display panel 001 is located. The first adhesive portion 810 can conduct the first binding electrode 201 and the first pad 310 or can conduct the second binding electrode 202 and the second pad 320. The projection of a second adhesive portion 820 on the plane on which the display panel 001 is located does not overlap the projection of the first binding electrode 201 on the plane on which the display panel 001 is located and the projection of the second binding electrode 202 on the plane on which the display panel 001 is located.

The conductive particles 801 are dispersed in the adhesive layer 800. The multiple first adhesive portions 810 include the adhesive layer 800 located between the binding electrodes and the pads, and the at least one second adhesive portion 820 includes the adhesive layer 800 not located between the binding electrodes and the pads. One side of the same one pad facing away from the base substrate 110 may be simultaneously provided with the first adhesive portion 810 and the second adhesive portion 820.

Using the light-emitting element 20 being the inverted structure and the first array substrate 10 including the first pad 310 and the second pad 320 as an example, the adhesive layer 800 is at least located on one side of the first pad 310 and the second pad 320 facing away from the base substrate 110. In an optional embodiment, the adhesive layer 800 is located on the side of the first pad 310 and the second pad 320 facing away from the base substrate 110, and the adhesive layer 800 located on the side of different pads facing away from the base substrate 100 is interrupted to avoid wrong conduction between the different pads.

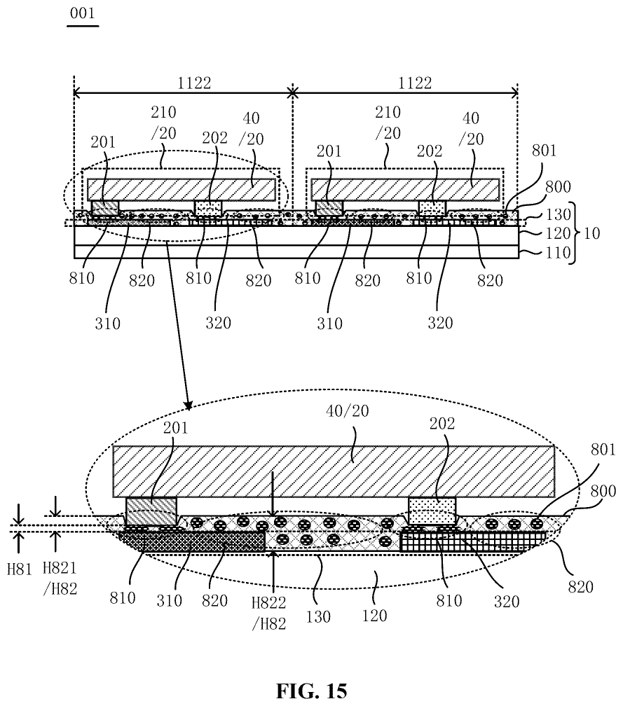

In another optional embodiment, FIG. 15 is another cross-section view according to an embodiment of the present disclosure. Referring to FIG. 15, the adhesive layer 800 is located on the side of the first pad 310 and the second pad 320 facing away from the base substrate 110, and the adhesive layer 800 located on the side of the different pads facing away from the base substrate 110 is interconnected, that is, the adhesive layer 800 may be an integrated structure and disposed as a whole layer. Exemplarily, conductive particles 801 may include conductors and an insulation film wrapping the conductors. When the conductive particles 801 are not pressed, the insulation film is intact, and the conductive particles 801 are not conductive; when the conductive particles 801 are pressed, the insulation film is ruptured, the internal conductor is exposed, and the conductive particles 801 are conductive. In this manner, the adhesive layer 800 between the different pads can be ensured not to be conductive to avoid the wrong conduction between the different pads.

In another optional embodiment, when the adhesive layer 800 is the integration structure and disposed as the whole layer, the adhesive layer 800 may include vinyl and thereby may also serve as a black matrix, and/or the adhesive layer 800 may include a light-absorbing material and thereby may also serve as a light-absorbing layer. In this manner, external light reflection can be reduced, and the contrast of the display panel 001 can be improved; light entering the circuit layer 120 can also be reduced, thereby preventing external light and/or light from the light-emitting element 20 from entering the circuit layer 120 to affect the electrical stability of transistors in the circuit layer 120.

With continued reference to FIGS. 14 and 15, the thickness of the first adhesive portion 810 in the perpendicular direction of the plane on which the display panel 001 is located is the first adhesive thickness H81, and the thickness of the second adhesive portion 820 in the perpendicular direction of the plane on which the display panel 001 is located is the second adhesive thickness H82. Among the at least some pixel disposition regions 1122, in the same one pixel disposition region 1122, the second adhesive thickness H82 is greater than the first adhesive thickness H81.

The second adhesive portion 820 is at least located on one side of pads facing away from the base substrate 110. The thickness of the second adhesive portion 820 located on the side of the pads facing away from the base substrate 110 is the first thickness H821. Among the at least some pixel disposition regions 1122, H821>H81. In other optional embodiments, the second adhesive portion 820 may also be located between the different pads, the thickness of the second adhesive portion 820 located between the different pads is the second thickness H822, and among the at least some pixel disposition regions 1122, H822>H821>H81.

Exemplarily, the light-emitting element 20 being the inverted structure and the first array substrate 10 including the first pad 310 and the second pad 320 is continuously used as an example. Before the multiple light-emitting elements 20 are transferred in batches to the multiple pixel disposition regions 1122 of the first array substrate 10, the adhesive layers 800 is first formed on one side of the first pads 310 and the second pads 320 facing away from the base substrate 110, and the multiple light-emitting elements 20 are transferred in batches to one side of the adhesive layer 800 facing away from the base substrate 110. A portion of the adhesive layer 800 that contacts the first binding electrode 201 or the second binding electrode 202 is the first adhesive portion 810, and a portion of the adhesive layer 800 that does not contact the first binding electrode 201 or the second binding electrode 202 is the second adhesive portion 820. In an embodiment, the projection of the first adhesive portion 810 on the plane on which the display panel 001 is located coincides with the projection of the first binding electrode 201 on the plane on which the display panel 001 is located or the projection of the second binding electrode 202 on the plane on which the display panel 001 is located. When the light-emitting element 20 is transferred to the side of the adhesive layer 800 facing away from the base substrate 110, the external force may be applied to the light-emitting element 20, or the gravity of the light-emitting element 20 may be used to cause the first binding electrode 201 of the light-emitting element 20 to press against the first adhesive portion 810 so that the thickness of the first adhesive portion 810 can have a smaller thickness, and conductive particles distributed in the first adhesive portion 810 can be secured between the binding electrodes and the pads to electrically connect the binding electrodes and the pads. Moreover, the light-emitting element 20 can also be firmly secured to the first array substrate 10, and the driving current in the first array substrate 10 can be transmitted to the light-emitting element 20 to drive the light-emitting element 20 to emit light.

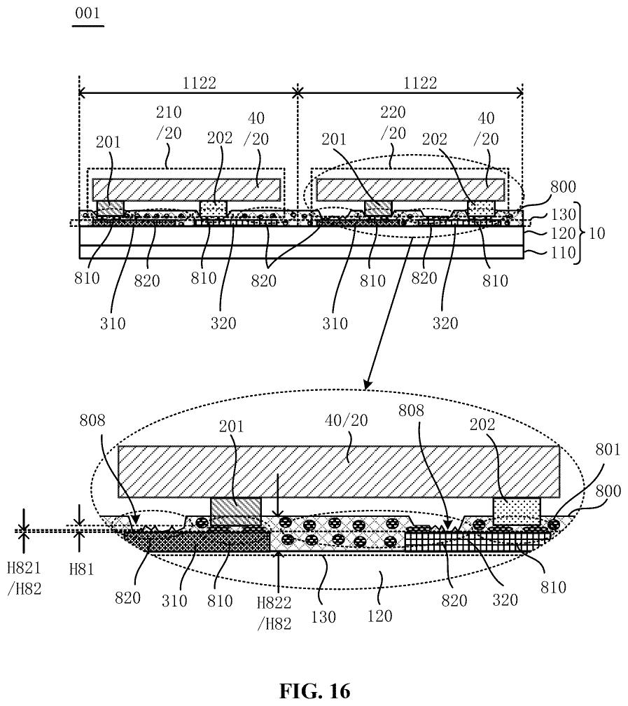

Based on the preceding embodiments, FIG. 16 is another cross-section view according to an embodiment of the present disclosure. Referring to FIG. 16, the light-emitting element 20 being the inverted structure and the first array substrate 10 including the first pad 310 and the second pad 320 is used as an example. If present, the damaged light-emitting element 20 needs to be removed. When the damaged light-emitting element 20 is removed, the binding electrodes of the damaged light-emitting element 20 may take part of the first adhesive portion 810 away so that the original first adhesive portion 810 can be damaged, and the thickness of some regions can be reduced. After the damaged light-emitting element 20 is removed, the light-emitting element 20 for repair may be transferred to the position of the originally damaged light-emitting element 20, the binding electrodes contact a region of the second adhesive portion 820 that does not contact the binding electrodes, the second adhesive portion 820 located under the binding electrodes become a new first adhesive portion 810, and the original first adhesive portion 810 becomes the second adhesive portion 820. In this case, in the same one pixel disposition region 1122, the second adhesive thickness H82 of part of the second adhesive portion 820 is less than the first adhesive thickness H81 of the first adhesive portion 810.

With continued reference to FIG. 16, among some pixel disposition regions 1122, when the damaged light-emitting element 20 is removed, the binding electrodes of the damaged light-emitting element 20 may take much of the first adhesive portion 810 away so that the thickness of the first adhesive portion 810 can be 0, and part of the first pad 310 and/or part of the second pad 320 can be exposed. After the light-emitting element 20 for repair is transferred to the position of the originally damaged light-emitting element 20, the second adhesive portion 820 located under the first binding electrode 201 becomes the new first adhesive portion 810, and the original first adhesive portion 810 becomes the second adhesive portion 820. In this case, among the some pixel disposition regions 1122, the second adhesive portion 820 includes a third hollow portion 808.

In an optional embodiment, in the same one pixel disposition region 1122, the projection of at least part of the third hollow portion 808 on the plane on which the display panel 001 is located overlaps the projection of the light-emitting element 20 on the plane on which the display panel is located. For one aspect, at least part of the projection of the repaired light-emitting element 20 on the plane on which the display panel 001 is located can be located within the projection of the damaged light-emitting element 20 on the plane on which the display panel 001 is located, thereby facilitating the reduction in the impact of repairing the display panel 001 on the resolution; for another aspect, the repaired light-emitting element 20 can block at least part of the third hollow portion 808 so that the external light reflection can be reduced, thereby facilitating the improvement in the contrast of the display panel 001 and so that the light entering the circuit layer 120 can also be reduced, facilitating the improvement in the electrical stability and thereby improving light pollution.

In another optional embodiment, when the damaged light-emitting element exists in the display panel, and after the damaged light-emitting element is removed, the thickness of the original first adhesive portion is reduced, or a hollow exists, and an adhesive (which is not shown in the figure) excluding the conductive particles may be coated on the original first adhesive portion so that the light pollution can be reduced. Moreover, the newly coated adhesive can also be prevented from covering other regions to cause wrong conduction, thereby facilitating the reduction in the processing difficulty when the adhesive is coated on the original first adhesive portion. If the conductive particles each include the conductor and the insulation film wrapping the conductor, an adhesive (which is not shown in the figure) including the conductive particles may also be coated on the original first adhesive portion, and the newly coated adhesive may be the same as the adhesive formed on the surface of the first array substrate before the multiple light-emitting elements are transferred in batches. In this manner, the adhesive excluding the conductive particles does not need to be provided additionally, thereby facilitating the reduction in the processing cost.

It is to be noted that the figure illustrates that the adhesive is located on one side of the light-emitting structure facing the base substrate, and a clearance exists between the adhesive and the light-emitting structure. In other optional embodiments, the adhesive may also contact the light-emitting structure, and the surface of one side of the adhesive facing away from the base substrate may be flush with the surface of one side of the binding electrodes facing away from the base substrate or is located on one side of the surface of one side of the binding electrodes facing away from the base substrate, where the surface of the side of the binding electrodes faces away from the base substrate.

In conclusion, referring to FIGS. 11 to 13, when the damaged light-emitting element 20 exists in the display panel 001, and after the damaged light-emitting element 20 is removed, the surfaces of the pads in the pixel disposition region 1122 take parts of the connection electrodes away to cause damage to the connection electrodes, or parts of the binding electrodes are left, which does not facilitate re-bonding; or referring to FIGS. 14 to 16, when the damaged light-emitting element 20 exists in the display panel 001, and after the damaged light-emitting element 20 is removed, the surface of the adhesive layer 800 in the pixel disposition region 1122 takes part of the adhesive layer 800 away, resulting in a poor adhesive effect, or part of the conductive particles 801 are taken away, resulting in poor conductivity. The area of the projection of the first pad 310 on the plane on which the first array substrate 10 is located is greater than or equal to N times the area of the projection of the first binding electrode 201 on the plane on which the first array substrate 10 is located, and/or the area of the projection of the second pad 320 on the plane on which the first array substrate 10 is located is greater than or equal to N times the area of the projection of the second binding electrode 202 on the plane on which the first array substrate 10 is located so that when the damaged light-emitting element 20 is repaired, and after the damaged light-emitting element 20 is removed, the surfaces of the pads do not need repairing, and the light-emitting element 20 that is used for repair and has intact functions can be directly placed within the pixel disposition region 1122 in which the originally damaged light-emitting element 20 is located. In this manner, while the repair complexity and difficulty are reduced, the impact on the resolution can also be reduced effectively, thereby facilitating the improvement in the yield and display effect of the display panel.

It is to be understood that if not in conflict, the embodiments of the present disclosure may be combined with the embodiment as shown in FIGS. 11 to 13 or the embodiment as shown in FIGS. 14 to 16. To simplify the drawing and facilitate description, the first connection electrode 710, the second connection electrode 720 and the adhesive layer 800 are no longer illustrated and shown in the embodiments below and corresponding drawings.

Optionally, within continued reference to FIGS. 3 to 10, the first pad 310 includes one first initialization bonding region 311 and at least one first repair bonding region 312, and/or the second pad 320 includes one second initialization bonding region 321 and at least one second repair bonding region 322. The first initialization bonding region 311 and the at least one first repair bonding region 312 are different regions, and the second initialization bonding region 321 and the at least one second repair bonding region 322 are also different regions.

The first initialization bonding region 311 is a bonding region in which the first binding electrode 201 of the light-emitting element 20 is bonded to the first pad 310 for the first time. A first repair bonding region 312 is a bonding region in which the first binding electrode 201 of the light-emitting element 20 is bonded to the first pad 310 for the second time. The second initialization bonding region 321 is a bonding region in which the second binding electrode 202 of the light-emitting element 20 is bonded to the second pad 320 for the first time. A second repair bonding region 322 is a bonding region in which the second binding electrode 202 of the light-emitting element 20 is bonded to the second pad 320 for the second time.

In an embodiment, the first pad 310 of the display panel 001 and/or the second pad 320 of the display panel 001 are provided with redundant bonding regions for the binding electrodes of the light-emitting element 20. When the damaged light-emitting element 20 exists, and after the damaged light-emitting element 20 is removed, the first binding electrode 201 of the light-emitting element 20 for repair may be bonded in the first repair bonding region 312 of the first pad 310, and/or the second binding electrode 202 of the light-emitting element 20 for repair may be bonded in the second repair bonding region 322 of the second pad 320, so electrodes left in the pads do not need removing, and connection electrodes on the surfaces of the pads do not need repairing, thereby facilitating the reduction in the process complexity and the repair difficulty. In the case where the electrodes left in the pads do not need removing, and the connection electrodes do not need repairing, the repair opportunities for the light-emitting element 20 in the pixel disposition region 1122 is equal to the number of first repair bonding regions 312 in the first pad or the number of second repair bonding regions 322 in the second pad 320. The number of first repair bonding regions 312 in the first pad and/or the number of second repair bonding regions 322 in the second pad 320 may be set according to actual requirements, which is not specifically limited in the embodiments of the present disclosure. To facilitate description and simplify the drawings, the first pad 310 including one first repair bonding region 312 and the second pad 320 including one second repair bonding region 322 is used as an example in the embodiments of the present disclosure.

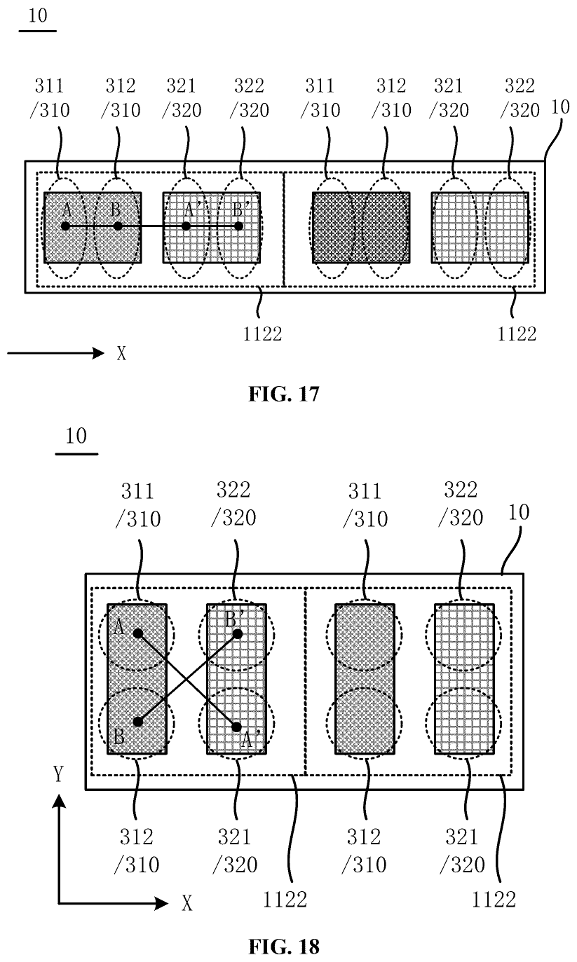

In an optional embodiment, FIG. 17 is a top view of a first array substrate according to an embodiment of the present disclosure, and FIG. 18 is another top view of a first array substrate according to an embodiment of the present disclosure. Referring to FIGS. 17 and 18, the pixel disposition region 1122 includes the first pad 310 and the second pad 320. The first pad 310 includes the one first initialization bonding region 311 and the at least one first repair bonding region 312, and the second pad 320 includes the one second initialization bonding region 321 and the at least one second repair bonding region 322. A connection line between the center of the first initialization bonding region 311 and the center of the second initialization bonding region 321 is a first connection line AA′, where the first initialization bonding region 311 and the second initialization bonding region 321 are located in the same one pixel disposition region 1122. A connection line between the center of the first repair bonding region 312 and the center of the second repair bonding region 322 is a second connection line BB′, where the first repair bonding region 312 and the second repair bonding region 322 are located in the same one pixel disposition region 1122. The first connection line AA′ overlaps the second connection line BB′.

Exemplarily, the light-emitting element 20 being the inverted structure is used as an example, and the first array substrate 10 includes the first pad 310 and the second pad 320. If the first pad 310 and the second pad 320 are arranged in the first direction X, the first initialization bonding region 311 and the first repair bonding region 312 that are in the first pad 310 are arranged in the first direction X, and the second initialization bonding region 321 and the second repair bonding region 322 that are in the second pad 320 are also arranged in the first direction X, as shown in FIG. 17, the first connection AA′ and the second connection line BB′ are parallel to each other and partially coincide with each other. If the first pad 310 and the second pad 320 are arranged in the first direction X, the first initialization bonding region 311 and the first repair bonding region 312 that are in the first pad 310 are arranged in the second direction Y, and the second initialization bonding region 321 and the second repair bonding region 322 that are in the second pad 320 are also arranged in the second direction Y, as shown in FIG. 18, the first connection AA′ intersects the second connection line BB′. The first direction X intersects the second direction Y, and the first direction X and the second direction Y are parallel to the plane on which the display panel 001 is located.

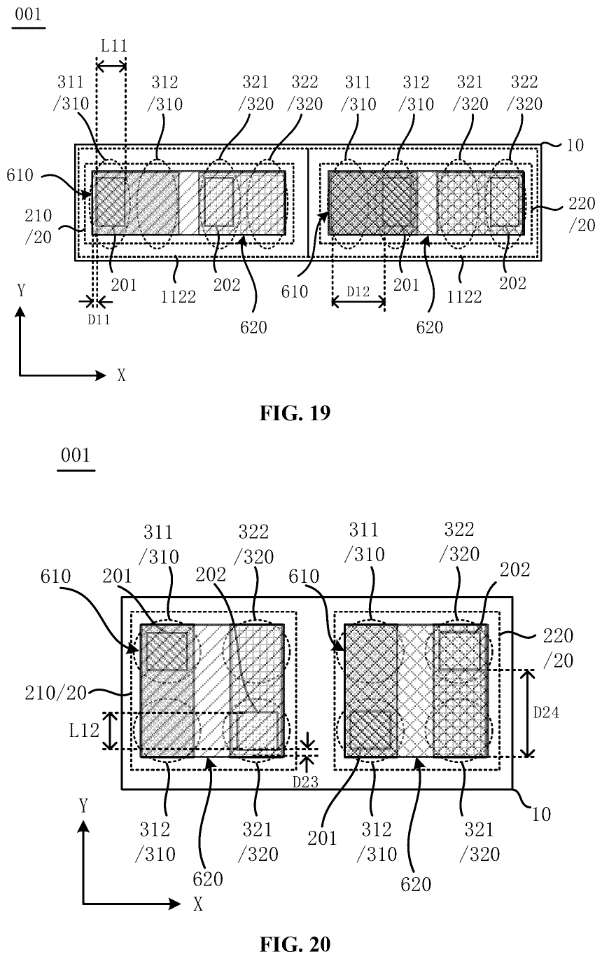

Based on the preceding embodiments, FIG. 19 is a partial top view corresponding to FIG. 17, and FIG. 20 is a partial top view corresponding to FIG. 18. Referring to FIGS. 19 and 20, when the light-emitting element 20 is bonded to the first initialization bonding region 311 of the first pad 310 and the second initialization bonding region 321 of the second pad 320 separately, the projection of the light-emitting element 20 on the plane on which the display panel 001 is located may overlap the projection of the first repair bonding region 312 of the first pad on the plane on which the display panel 001 is located and/or the projection of the second repair bonding region 322 of the second pad on the plane on which the display panel 001 is located; or when the light-emitting element 20 is bonded to the first repair bonding region 312 of the first pad 310 and the second repair bonding region 322 of the second pad 320 separately, the projection of the light-emitting element 20 on the plane on which the display panel 001 is located may overlap the projection of the first initialization bonding region 311 of the first pad on the plane on which the display panel 001 is located and/or the projection of the second initialization bonding region 321 of the second pad on the plane on which the display panel 001 is located. In this manner, the projection of the light-emitting element 20 on the plane on which the display panel 001 is located at least overlaps the projections of three bonding regions on the plane on which the display panel 001 is located so that at least some redundant bonding regions can be located under the light-emitting element 20. Compared with the related art in which redundant pads are provided and located outside the position under the light-emitting element, this can effectively reduce the size of the pixel disposition region 1122 so that the impact of the arrangement of redundant bonding regions in the first pad 310 and/or the second pad 320 on the size of the pixel disposition region 1122 can be reduced, and the number of pixel disposition regions 1122 per unit area can be increased, thereby improving the resolution and display effect of the display panel 001.

As a feasible embodiment, with continued reference to FIGS. 19 and 20, a light-emitting element 20 in the display panel 001 is a first light-emitting element 210. The first binding electrode 201 of the first light-emitting element 210 is bonded to the first initialization bonding region 311 of the first pad 310, and the second binding electrode 202 of the first light-emitting element 210 is bonded to the second initialization bonding region 321 of the second pad 320. The first light-emitting element 210 is a light-emitting element 20 that is placed in the pixel disposition region 1122 originally and has not been repaired. In an embodiment, all the multiple light-emitting elements 20 in the display panel 001 are first light-emitting elements 210, that is, all the multiple light-emitting elements 20 in the display panel 001 are not damaged, and the multiple light-emitting elements 20 in all the multiple pixel disposition regions 1122 have not been repaired. All the multiple light-emitting elements 20 are light-emitting elements 20 that are placed in the multiple pixel disposition regions 1122 originally. In another embodiment, some light-emitting elements 20 in the display panel 001 are first light-emitting elements 210, that is, light-emitting elements 20 in some pixel disposition regions 1122 in the display panel 001 have been repaired, and the some light-emitting elements 20 are not light-emitting elements 20 that are placed in pixel disposition regions 1122 originally.

Exemplarily, the light-emitting element 20 being the inverted structure is used as an example, and the first array substrate 10 includes the first pad 310 and the second pad 320. Referring to FIGS. 19 and 20, the projection of the first light-emitting element 210 on the plane on which the display panel 001 is located overlaps the projection of the first initialization bonding region 311 on the plane on which the display panel 001 is located and the projection of the second initialization bonding region 321 on the plane on which the display panel 001 is located. Based on this, the projection of the first light-emitting element 210 on the plane on which the display panel 001 is located further overlaps the projection of the first repair bonding region 312 on the plane on which the display panel 001 is located and/or the projection of the second repair bonding region 322 on the plane on which the display panel 001 is located. The first repair bonding region 312 and/or the second repair bonding region 322 are redundant bonding regions disposed for the binding electrodes of the light-emitting element 20. At least some redundant bonding regions of the first repair bonding region 312 and/or the second repair bonding region 322 are disposed under the first light-emitting element 210 so that the space of the light-emitting element 20 in the display panel 001 occupied by the arrangement of the redundant bonding regions can be reduced, thereby facilitating the improvement in the resolution of the display panel 001.

As a feasible embodiment, with continued reference to FIGS. 19 and 20, another light-emitting element 20 in the display panel 001 is a second light-emitting element 220. The first binding electrode 201 of the second light-emitting element 220 is bonded to the first repair bonding region 312 of the first pad 310, and/or the second binding electrode 202 of the second light-emitting element 220 is bonded to the second repair bonding region 322 of the second pad 320. The second light-emitting element 220 is a light-emitting element 20 that is not placed in the pixel disposition region 1122 originally and has been repaired.

Exemplarily, the projection of the second light-emitting element 220 on the plane on which the display panel 001 is located overlaps the projection of the first repair bonding region 312 on the plane on which the display panel 001 is located and/or the projection of the second repair bonding region 322 on the plane on which the display panel 001 is located. Based on this, the projection of the second light-emitting element 220 on the plane on which the display panel 001 is located overlaps the projection of the first initialization bonding region 311 on the plane on which the display panel 001 is located and/or the projection of the second initialization bonding region 321 on the plane on which the display panel 001 is located. In the same one pixel disposition region 1122, at least part of the projection of the second light-emitting element 220 on the plane on which the display panel 001 is located belongs to the projection of an originally damaged first light-emitting element 210 on the plane on which the display panel 001 is located. In the same one pixel disposition region 1122, the projections of the light-emitting element 20 before and after repair on the plane on which the display panel 001 is located at least partially coincide, so the second light-emitting element 220 may be replaced in the position of the originally damaged light-emitting element 20, or the second light-emitting element 220 is replaced only after the originally damaged light-emitting element 20 is displaced by a minimal distance, thereby facilitating the impact of repairing the display panel 001 on the resolution and improving the display effect.

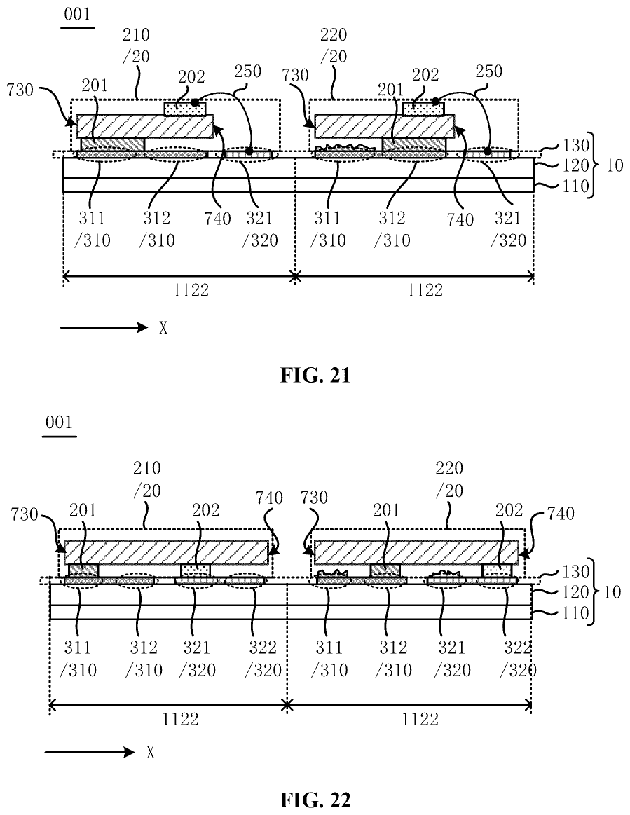

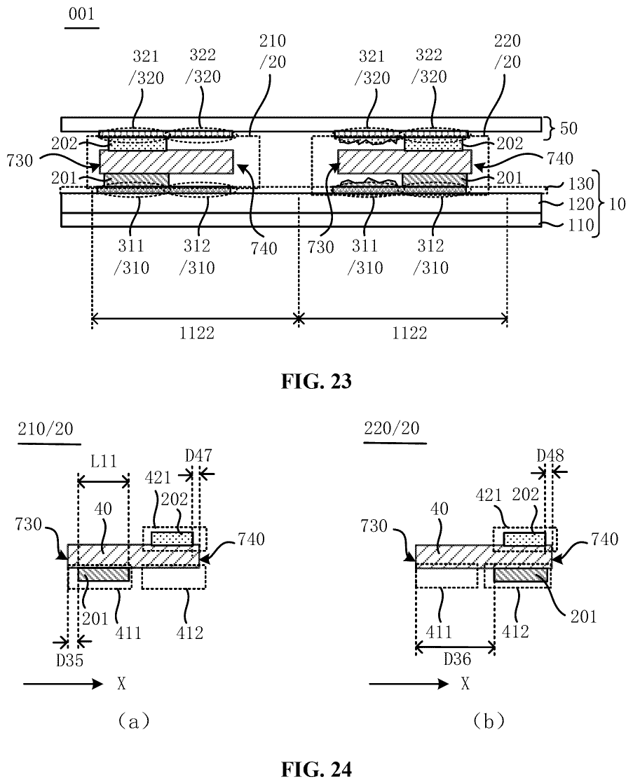

In a feasible embodiment, FIG. 21 is a cross-section view of a display panel in FIG. 3 taken along the section line F101-F101′. In another feasible embodiment, FIG. 22 is another cross-section view of a display panel in FIG. 5 taken along the section line F102-F102′. In another feasible embodiment, FIG. 23 is a cross-section view of a display panel in FIG. 9 taken along the section line F104-F104′. Referring to FIGS. 3, 5, 9 and 21 to 23, the display panel 001 includes a first light-emitting element 210 and a second light-emitting element 220. The position of the first binding electrode 201 of the first light-emitting element 210 in the first pad 310 is different from the position of the first binding electrode 201 of the second light-emitting element 220 in the first pad 310, and/or the position of the second binding electrode 202 of the first light-emitting element 210 in the second pad 320 is different from the position of the second binding electrode 202 of the second light-emitting element 220 in the second pad 320.

It is to be understood that FIGS. 21 to 23 exemplarily illustrate that the first initialization bonding region 311 in a pixel disposition region 1122 in which the second light-emitting element 220 is located is left with part of the binding electrodes, and/or the second initialization bonding region 321 in the pixel disposition region 1122 in which the second light-emitting element 220 is located is left with part of the binding electrodes. To facilitate description and simplify the drawings, the residual binding electrodes are no longer shown in other drawings.

Optionally, with continued reference to FIGS. 19 and 20, the light-emitting element 20 being the inverted structure and the first array substrate 10 including the first pad 310 and the second pad 320 is used as an example for illustration. The pixel disposition region 1122 includes a first edge 610 in the arrangement direction of the first pad 310 and the second pad 320 and close to the first pad 310 and further includes a second edge 620 adjacent to the first edge 610. The multiple light-emitting elements 20 include the first light-emitting element 210 and the second light-emitting element 220. The distance from the first binding electrode 201 of the first light-emitting element 210 to the first edge 610 is the first distance D11. The distance from the first binding electrode 201 of the second light-emitting element 220 to the first edge 610 is the second distance D12. The distance from the second binding electrode 202 of the first light-emitting element 210 to the second edge 620 is the third distance D23. The distance from the second binding electrode 202 of the second light-emitting element 220 to the second edge 620 is the fourth distance D24. The first distance D11 is not equal to the second distance D12, and/or the third distance D23 is not equal to the fourth distance D24.

The first distance D11 refers to the distance in the first direction X from the projection of the first binding electrode of the first light-emitting element 210 on the plane on which the display panel 001 is located to the projection of the first edge 610 of the pixel disposition region 1122 on the plane on which the display panel 001 is located. The second distance D12 refers to the distance in the first direction X from the projection of the first binding electrode 201 of the second light-emitting element 220 on the plane on which the display panel 001 is located to the projection of the first edge 610 of the pixel disposition region 1122 on the plane on which the display panel 001 is located. The third distance D23 refers to the distance in the second direction Y from the projection of the second binding electrode 202 of the first light-emitting element 210 on the plane on which the display panel 001 is located to the projection of the second edge 620 of the pixel disposition region 1122 on the plane on which the display panel 001 is located. The fourth distance D24 refers to the distance in the second direction Y from the projection of the second binding electrode 202 of the second light-emitting element 220 on the plane on which the display panel 001 is located to the projection of the second edge 620 of the pixel disposition region 1122 on the plane on which the display panel 001 is located. The first direction X is the arrangement direction of the first pad 310 and the second pad 320. The second direction Y intersects the first direction X. In a feasible embodiment, the projection of the light-emitting element 20 on the plane on which the display panel 001 is located coincides with the projection of the pixel disposition region 1122 on the plane on which the display panel 001 is located.

In an embodiment, the first distance D11 being not equal to the second distance D12 illustrates that the first binding electrode 201 of the first light-emitting element 210 and the first binding electrode 201 of the second light-emitting element 220 are located at different positions of first pads 310 in pixel disposition regions 1122 respectively, and the third distance D23 being not equal to the fourth distance D24 illustrates that the second binding electrode 202 of the first light-emitting element 210 and the second binding electrode 202 of the second light-emitting element 220 are located at different positions of second pads 320 in pixel disposition regions 1122 respectively, that is, a bonding region in which the first binding electrode 201 of the second light-emitting element 220 is located and/or a bonding region in which the second binding electrode 202 of the second light-emitting element 220 is located are different from bonding regions in which the binding electrodes of the first light-emitting element 210 are located.

Exemplarily, if the first initialization bonding region 311 and the first repair bonding region 312 that are in the first pad 310 are arranged in the first direction X, and the second initialization bonding region 321 and the second repair bonding region 322 that are in the second pad 320 are also arranged in the first direction X, as shown in FIG. 19, compared with the first binding electrode 201 of the first light-emitting element 210, the first binding electrode 201 of the second light-emitting element 220 is displaced in the direction facing away from or facing the first edge 610; compared with the second binding electrode 202 of the first light-emitting element 210, the second binding electrode 202 of the second light-emitting element 220 is displaced in the direction facing away from or facing the first edge 610. If the first initialization bonding region 311 and the first repair bonding region 312 that are in the first pad 310 are arranged in the second direction Y, and the second initialization bonding region 321 and the second repair bonding region 322 that are in the second pad 320 are also arranged in the second direction Y, as shown in FIG. 20, compared with the first binding electrode 201 of the first light-emitting element 210, the first binding electrode 201 of the second light-emitting element 220 is displaced in the direction facing away from or facing the second edge 620; compared with the second binding electrode 202 of the first light-emitting element 210, the second binding electrode 202 of the second light-emitting element 220 is displaced in the direction facing away from or facing the second edge 620.

Based on the preceding embodiments, with continued reference to FIGS. 19 and 20, the absolute value of the difference between the second distance D12 and the first distance D11 is greater than the length L11 of the first binding electrode 201 in the first direction X, and/or the absolute value of the difference between the fourth distance D24 and the third distance D23 is greater than the length L12 of the second binding electrode 202 in the second direction Y. The absolute value of the difference between the second distance D12 and the first distance D11 is the distance by which the first binding electrode 201 of the second light-emitting element 220 is displaced in the direction facing away from or facing the first edge 610 relative to the first binding electrode 201 of the first light-emitting element 210. The distance is greater than the length L11 of the first binding electrode 201 in the first direction X so that the first binding electrode 201 of the second light-emitting element 220 cannot be bonded in the first initialization bonding region 311 in which the first binding electrode 201 of the first light-emitting element 210 is left, that is, the first repair bonding region 312 of the first pad 310 in which the first binding electrode 201 of the second light-emitting element 220 is located does not overlap the first initialization bonding region 311 of the first pad 310 in which the first binding electrode 201 of the first light-emitting element 210 is located. The absolute value of the difference between the fourth distance D24 and the third distance D23 is the distance by which the second binding electrode 202 of the second light-emitting element 220 is displaced in the direction facing away from or facing the second edge 620 relative to the second binding electrode 202 of the first light-emitting element 210. The distance is greater than the length L12 of the second binding electrode 202 in the second direction Y so that the second binding electrode 202 of the second light-emitting element 220 cannot be bonded in the second initialization bonding region 321 in which the second binding electrode 202 of the first light-emitting element 210 is left, that is, the second repair bonding region 322 of the second pad 320 in which the second binding electrode 202 of the second light-emitting element 220 is located does not overlap the second initialization bonding region 321 of the second pad 320 in which the second binding electrode 202 of the first light-emitting element 210 is located. In this manner, when the damaged light-emitting element 20 is repaired, the electrodes left on the pads do not need removing, thereby simplifying the process complexity of the repair, and the pads do not need repairing, thereby reducing the repair difficulty.

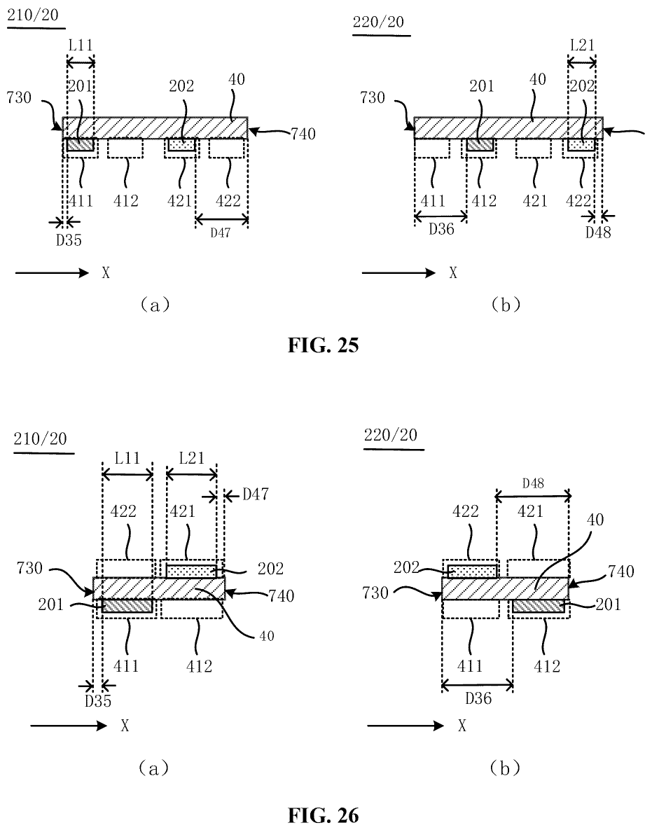

Optionally, FIG. 24 is a diagram illustrating the structure of a first light-emitting element and a second light-emitting element according to an embodiment of the present disclosure, FIG. 25 is another diagram illustrating the structure of a first light-emitting element and a second light-emitting element according to an embodiment of the present disclosure, and FIG. 26 is another diagram illustrating the structure of a first light-emitting element and a second light-emitting element according to an embodiment of the present disclosure. The light-emitting elements 20 in FIG. 24 correspond to the display panel 001 and light-emitting elements 20 thereof in FIGS. 3 and 21. The light-emitting elements 20 in FIG. 25 correspond to the display panel 001 and light-emitting elements 20 thereof in FIGS. 5 and 22. The light-emitting elements 20 in FIG. 26 correspond to the display panel 001 and light-emitting elements 20 thereof in FIGS. 9 and 23. The first light-emitting element 210 is the light-emitting element 20 that is placed in the pixel disposition region 1122 originally and has not been repaired. The second light-emitting element 220 is the light-emitting element 20 that is not placed in the pixel disposition region 1122 originally and has been repaired. “Correspond to” only means that the structure types of the light-emitting elements 20 are the same and that the light-emitting elements 20 may be applied to corresponding display panels 001 and does not mean that the structures of corresponding light-emitting elements 20 are exactly the same. In a feasible embodiment, the light-emitting elements 20 in FIGS. 24 to 26 may be different from light-emitting elements 20 in the corresponding display panels 001 in terms of structure.

Referring to FIGS. 24 to 26, the light-emitting element 20 includes the light-emitting structure 40, and the light-emitting structure 40 includes a first initialization electrode region 411 and a second initialization electrode region 421. A light-emitting element 20 in the display panel 001 is the first light-emitting element 210. The first binding electrode 201 of the first light-emitting element 210 is located in the first initialization electrode region 411, and the second binding electrode 202 of the first light-emitting element 210 is located in the second initialization electrode region 421. For the second light-emitting element 220 for repair, the first binding electrode 201 of the second light-emitting element 220 may be located in the first initialization electrode region 411 of the light-emitting structure 40 or may also be located outside the first initialization electrode region 411 of the light-emitting structure 40, and the second binding electrode 202 of the second light-emitting element 220 may be located in the second initialization electrode region 421 of the light-emitting structure 40 or may also be located outside the second initialization electrode region 421 of the light-emitting structure 40, which is not limited in the embodiments of the present disclosure.

In an optional embodiment, the position of the first binding electrode 201 of the second light-emitting element 220 in the light-emitting structure 40 is different from the position of the first binding electrode 201 of the first light-emitting element 210 in the light-emitting structure 40, and/or the position of the second binding electrode 202 of the second light-emitting element 220 in the light-emitting structure 40 is different from the position of the second binding electrode 202 of the first light-emitting element 210 in the light-emitting structure 40.

In an exemplary embodiment, referring to FIGS. 21, 23, 24 and 26, the first initialization electrode region 411 and the second initialization electrode region 421 are located on two opposite sides of the light-emitting structure 40 respectively, and the light-emitting structure 40 further includes at least one first repair electrode region 412 and/or at least one second repair electrode region 422. The first initialization electrode region 411 and the at least one first repair electrode region 412 are located on the same side of the light-emitting structure 40 and are different regions. The second initialization electrode region 421 and the at least one second repair electrode region 422 are located on the same side of the light-emitting structure 40 and are different regions. In the display panel 001, a light-emitting element 20 is a first light-emitting element 210, and another light-emitting element 20 is the second light-emitting element 220. The first binding electrode 201 of the second light-emitting element 220 is located in a first repair electrode region 412, and/or the second binding electrode 202 of the second light-emitting element 220 is located in a second repair electrode region 422.

Exemplarily, the light-emitting element 20 is the perpendicular structure. In a feasible embodiment, the first binding electrode 201 of the light-emitting element 20 is bonded to the first pad 310, and the second binding electrode 202 of the light-emitting element 20 may be electrically connected to the second pad 320 through the lead 250, as shown in FIG. 21. In this case, the projection of the first binding electrode 201 of the first light-emitting element 210 on the plane on which the display panel 001 is located may not overlap the projection of the second binding electrode 202 of the first light-emitting element 210 on the plane on which the display panel 001 is located, and the projection of the first binding electrode 201 of the second light-emitting element 220 on the plane on which the display panel 001 is located may overlap the projection of the second binding electrode 202 of the second light-emitting element 220 on the plane on which the display panel 001 is located, as shown in FIG. 24; or the projection of the first binding electrode 201 of the first light-emitting element 210 on the plane on which the display panel 001 is located may overlap the projection of the second binding electrode 202 of the first light-emitting element 210 on the plane on which the display panel 001 is located, and the projection of the first binding electrode 201 of the second light-emitting element 220 on the plane on which the display panel 001 is located does not overlap the projection of the second binding electrode 202 of the second light-emitting element 220 on the plane on which the display panel 001 is located. Compared with the first light-emitting element 210, the position of the first binding electrode 201 in the second light-emitting element 220 for being bonded to the first pad 310 in the light-emitting structure 40 changes while the position of the second binding electrode 202 in the second light-emitting element 220 for being electrically connected to the second pad 320 through the lead 250 in the light-emitting structure 40 may not change. That is, the first binding electrode 201 of the second light-emitting element 220 for repair and the first binding electrode 201 of the first light-emitting element 210 are located in different electrode regions, and the second binding electrode 202 of the second light-emitting element 220 for repair and the second binding electrode 202 of the first light-emitting element 210 may be located in the same electrode region.

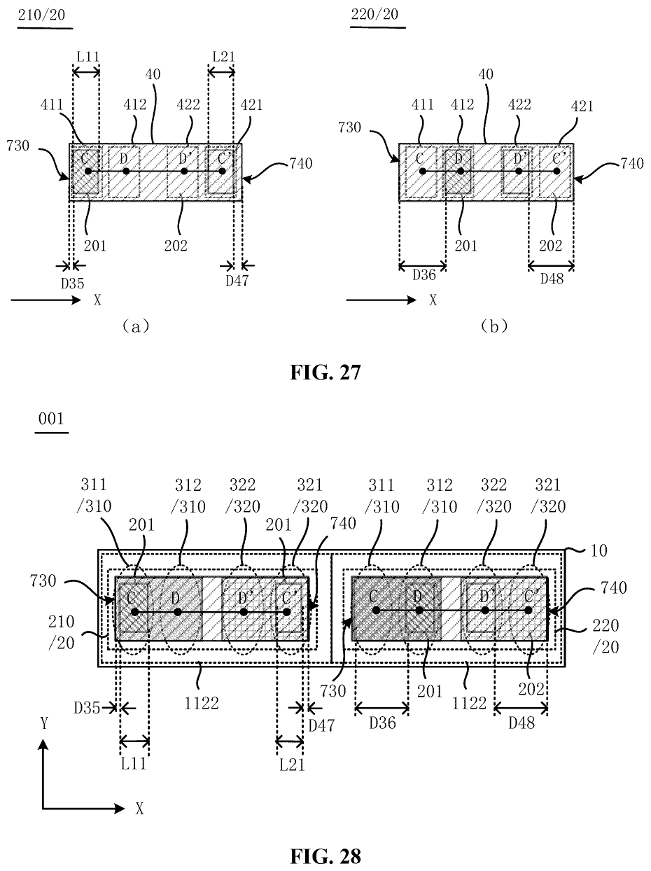

In another feasible embodiment, the light-emitting element 20 is the perpendicular structure, the first binding electrode 201 of the light-emitting element 20 is bonded to the first pad 310 of the first array substrate 10, and the second binding electrode 202 of the light-emitting element 20 is bonded to the second pad 320 of the second substrate 50, as shown in FIG. 23. In this case, the projection of the first binding electrode 201 of the first light-emitting element 210 on the plane on which the display panel 001 is located may not overlap the projection of the second binding electrode 202 of the first light-emitting element 210 on the plane on which the display panel 001 is located, and the projection of the first binding electrode 201 of the second light-emitting element 220 on the plane on which the display panel 001 is located may also not overlap the projection of the second binding electrode 202 of the second light-emitting element 220 on the plane on which the display panel 001 is located, as shown in FIG. 27; or the projection of the first binding electrode 201 of the first light-emitting element 210 on the plane on which the display panel 001 is located may overlap the projection of the second binding electrode 202 of the first light-emitting element 210 on the plane on which the display panel 001 is located, and the projection of the first binding electrode 201 of the second light-emitting element 220 on the plane on which the display panel 001 is located may also overlap the projection of the second binding electrode 202 of the second light-emitting element 220 on the plane on which the display panel 001 is located, which is shown in the first light-emitting element 210 and the second light-emitting element 220 in FIG. 23. Compared with the first light-emitting element 210, the position of the first binding electrode 201 in the second light-emitting element 220 for being bonded to the first pad 310 in the light-emitting structure 40 changes while the position of the second binding electrode 202 in the second light-emitting element 220 for being bonded to the second pad 320 in the light-emitting structure 40 also changes. That is, the first binding electrode 201 of the second light-emitting element 220 for repair and the first binding electrode 201 of the first light-emitting element 210 are located in different electrode regions, and the second binding electrode 202 of the second light-emitting element 220 for repair and the second binding electrode 202 of the first light-emitting element 210 are also located in different electrode regions.

In another exemplary embodiment, referring to FIGS. 21 and 25, the light-emitting structure 40 includes the at least one first repair electrode region 412 and the at least one second repair electrode region 422, and the first initialization electrode region 411, the second initialization electrode region 421, the at least one first repair electrode region 412 and the at least one second repair electrode region 422 are located on the same side of the light-emitting structure 40. In the display panel 001, a light-emitting element 20 is the first light-emitting element 210, and another light-emitting element 20 is the second light-emitting element 220. The first binding electrode 201 of the second light-emitting element 220 is located in the first repair electrode region 412, and the second binding electrode 202 of the second light-emitting element 220 is located in the second repair electrode region 422. The first initialization electrode region 411 and the at least one first repair electrode region 412 are different regions, and the second initialization electrode region 421 and the at least one second repair electrode region 422 are also different regions.

Exemplarily, the light-emitting element 20 being the inverted structure is used as an example. The first binding electrode 201 of the light-emitting element 20 is bonded to the first pad 310 of the first array substrate 10, and the second binding electrode 202 of the light-emitting element 20 is bonded to the second pad 320 of the first array substrate 10. Moreover, a bonding region between the first binding electrode 201 of the first light-emitting element 210 and the first pad 310 is different from a bonding region between the first binding electrode 201 of the second light-emitting element 220 and the first pad 310, and a bonding region between the second binding electrode 202 of the first light-emitting element 210 and the second pad 320 is different from a bonding region between the second binding electrode 202 of the second light-emitting element 220 and the second pad 320. Compared with the first light-emitting element 210, the positions of the first binding electrode 201 and the second binding electrode 202 that are in the second light-emitting element 220 in the light-emitting structure 40 change, that is, the first binding electrode 201 of the second light-emitting element 220 for repair and the first binding electrode 201 of the first light-emitting element 210 are located in different electrode regions of the light-emitting structure 40, and the second binding electrode 202 of the second light-emitting element 220 for repair and the second binding electrode 202 of the first light-emitting element 210 are also located in different electrode regions of the light-emitting structure 40.

Based on the preceding embodiments, referring to FIGS. 21 to 26, the multiple light-emitting elements 20 include the first light-emitting element 210 and the second light-emitting element 220, the first light-emitting element 210 and the second light-emitting element 220 each include the light-emitting structure 40, and the first binding electrode 201 and the second binding electrode 202 are located in the light-emitting structure 40. The projection of the first binding electrode 201 of the first light-emitting element 210 on the plane on which the display panel 001 is located and the projection of the second binding electrode 202 of the first light-emitting element 210 on the plane on which the display panel 001 is located are arranged in the first direction X parallel to the plane on which the display panel 001 is located. The light-emitting structure 40 includes a third edge 730 and a fourth edge 740 that are arranged in the first direction X. In the same one pixel disposition region 1122, the third edge 730 is close to the first binding electrode 201 of the first light-emitting element 210, and the fourth edge 740 is close to the second binding electrode 202 of the first light-emitting element 210. The third edge 730 of the first light-emitting element 210 and the third edge 730 of the second light-emitting element 220 are located on the same sides of the internal light-emitting structures 40. The fourth edge 740 of the first light-emitting element 210 and the fourth edge 740 of the second light-emitting element 220 are located on the same sides of the internal light-emitting structures 40.

Referring to FIGS. 24 to 26, the distance from the first binding electrode 201 of the first light-emitting element 210 to the third edge 730 is the fifth distance D35, the distance from the first binding electrode 201 of the second light-emitting element 220 to the third edge 730 is the sixth distance D36, the distance from the second binding electrode 202 of the first light-emitting element 210 to the fourth edge 740 is the seventh distance D47, and the distance from the second binding electrode 202 of the second light-emitting element 220 to the fourth edge 740 is the eighth distance D48; the fifth distance D35 is not equal to the sixth distance D36, and/or the seventh distance D47 is not equal to the eighth distance D48.

The fifth distance D35 refers to the distance in the first direction X from the projection of the first binding electrode of the first light-emitting element 210 on the plane on which the display panel 001 is located to the projection of the third edge 730 of the internal light-emitting structure 40 on the plane on which the display panel 001 is located. The sixth distance D36 refers to the distance in the first direction X from the projection of the first binding electrode 201 of the second light-emitting element 220 on the plane on which the display panel 001 is located to the projection of the third edge 730 of the internal light-emitting structure 40 on the plane on which the display panel 001 is located. The seventh distance D47 refers to the distance in the first direction X from the projection of the second binding electrode 202 of the first light-emitting element 210 on the plane on which the display panel 001 is located to the projection of the fourth edge 740 of the internal light-emitting structure 40 on the plane on which the display panel 001 is located. The eighth distance D48 refers to the distance in the first direction X from the projection of the second binding electrode 202 of the second light-emitting element 220 on the plane on which the display panel 001 is located to the projection of the fourth edge 740 of the internal light-emitting structure 40 on the plane on which the display panel 001 is located. In a feasible embodiment, the light-emitting structure 40 of the first light-emitting element 210 is the same as the light-emitting structure 40 of the second light-emitting element 220, the first binding electrode 201 of the first light-emitting element 210 is the same as the first binding electrode 201 of the second light-emitting element 220 in terms of structure, and the second binding electrode 202 of the first light-emitting element 210 is the same as the second binding electrode 202 of the second light-emitting element 220 in terms of structure.

In an embodiment, the fifth distance D35 being not equal to the sixth distance D36 illustrates that the first binding electrode 201 of the first light-emitting element 210 and the first binding electrode 201 of the second light-emitting element 220 are located at different positions on sides of the light-emitting structures 40 respectively and that the first binding electrode 201 of the first light-emitting element 201 is closer to the third edge 730 of the light-emitting structure 40; the seventh distance D47 being not equal to the eighth distance D48 illustrates that the second binding electrode 202 of the first light-emitting element 210 and the second binding electrode 202 of the second light-emitting element 220 are located at different positions on sides of the light-emitting structures 40 respectively, that is, an electrode region in which the first binding electrode 201 of the second light-emitting element 220 is located and/or an electrode region in which the second binding electrode 202 of the second light-emitting element 220 is located are different from electrode regions in which the binding electrodes of the first light-emitting element 210 are located.

Exemplarily, the first initialization electrode region 411 and the first repair electrode region 412 are arranged in the first direction X, and/or the second initialization electrode region 421 and the second repair electrode region 422 are arranged in the first direction X. Compared with the first binding electrode 201 of the first light-emitting element 210, the first binding electrode 201 of the second light-emitting element 220 is displaced in the direction facing away from the third edge 730; and/or compared with the second binding electrode 202 of the first light-emitting element 210, the second binding electrode 202 of the second light-emitting element 220 is displaced in the direction facing away from or facing the fourth edge 740.

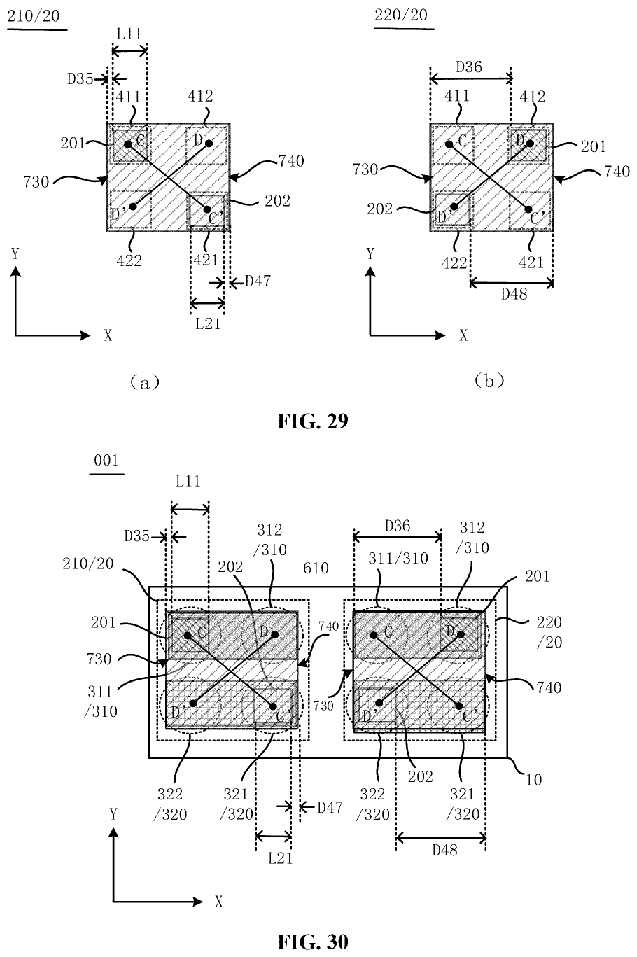

In a feasible embodiment, FIG. 27 is a top view of a first light-emitting element and a second light-emitting element according to an embodiment of the present disclosure, FIG. 28 is a top view of a display panel to which a first light-emitting element and a second light-emitting element in FIG. 27 are applied, FIG. 29 is another top view of a first light-emitting element and a second light-emitting element according to an embodiment of the present disclosure, and FIG. 30 is a top view of a display panel to which a first light-emitting element and a second light-emitting element in FIG. 29 are applied. The light-emitting element 20 being the inverted structure and the first array substrate 10 including the first pad 310 and the second pad 320 is used as an example for illustration. When the first initialization electrode region 411 and the first repair electrode region 412 are arranged in the first direction X, and the second initialization electrode region 421 and the second repair electrode region 422 are also arranged in the first direction X, the first pad 310 and the second pad 320 may also be arranged in the first direction X, as shown in FIGS. 27 and 28; or the arrangement direction of the first pad 310 and the second pad 320 may also intersect the first direction X, and as shown in FIGS. 29 and 30, the first pad 310 and the second pad 320 may be arranged in the second direction Y intersecting the first direction X.

Referring to FIGS. 24 to 30, the absolute value of the difference between the sixth distance D36 and the fifth distance D35 is greater than the length L11 of the first binding electrode 201 in the first direction X, and the absolute value of the difference between the eighth distance D48 and the seventh distance D47 is greater than the length L21 of the second binding electrode 202 in the first direction X. The absolute value of the difference between the sixth distance D36 and the fifth distance D35 is the distance by which the first binding electrode 201 of the second light-emitting element 220 is displaced in the direction facing away from the third edge 730 relative to the first binding electrode 201 of the first light-emitting element 210. The distance is greater than the length L11 of the first binding electrode 201 in the first direction X so that the first binding electrode 201 of the second light-emitting element 220 cannot be bonded in the first initialization bonding region 311 in which the first binding electrode 201 of the first light-emitting element 210 is left, that is, the first repair electrode region 412 in which the first binding electrode 201 of the second light-emitting element 220 is located does not overlap the first initialization electrode region 411 in which the first binding electrode 201 of the first light-emitting element 210 is located. The absolute value of the difference between the eighth distance D48 and the seventh distance D47 is the distance by which the second binding electrode 202 of the second light-emitting element 220 is displaced in the direction facing away from or facing the fourth edge 740 relative to the second binding electrode 202 of the first light-emitting element 210. The distance is greater than the length L21 of the second binding electrode 202 in the first direction X so that the second binding electrode 202 of the second light-emitting element 220 cannot be bonded in the second initialization bonding region 321 in which the second binding electrode 202 of the first light-emitting element 210 is left, that is, the second repair electrode region 422 in which the second binding electrode 202 of the second light-emitting element 220 is located does not overlap the second initialization electrode region 421 in which the second binding electrode 202 of the first light-emitting element 210 is located.

In this manner, when the damaged first light-emitting element 210 is repaired, the second light-emitting element 220 may be bonded to the first pad 310 and the second pad 320 in the original position of the first light-emitting element 210, and bonding regions of the first binding electrode 201 of the second light-emitting element 220 and the second binding electrode 202 of the second light-emitting element 220 can avoid bonding regions of the first binding electrode 201 of the first light-emitting element 210 and the second binding electrode 202 of the first light-emitting element 210. Therefore, the electrodes left on the pads do not need removing, and the connection electrodes on the surfaces of the pads do not need repairing so that the process complexity of the repair can be simplified, and the repair difficulty can be reduced. Moreover, the in-situ repair of the light-emitting element 20 can be achieved so that the impact on the resolution can be reduced effectively, thereby facilitating the improvement in the display effect of the display panel 001.

In another feasible embodiment, with continued reference to FIGS. 27 and 29, a connection line between the center of the first initialization electrode region 411 and the center of the second initialization electrode region 421 is a third connection line CC′, where the first initialization electrode region 411 and the second initialization electrode region 421 are located in the same one light-emitting structure 40, and a connection line between the center of the first repair electrode region 412 and the center of the second repair electrode region 422 is a fourth connection line DD′, where the first repair electrode region 412 and the second repair electrode region 422 are located in the same one light-emitting structure 40; the third connection line CC′ overlaps the fourth connection line DD′. Electrode regions of the light-emitting structure 40 correspond to bonding regions of the pads respectively. The third connection line CC′ overlaps the fourth connection line DD′ so that the projection of the light-emitting element 20 on the plane on which the display panel 001 is located can simultaneously overlap the projections of the initialization bonding (311 and 321) regions on the plane on which the display panel 001 is located and the projections of the repair bonding regions (312 and 322) on the plane on which the display panel 001 is located, thereby reducing the space of the pixel disposition region 1122 in the display panel 001 occupied by the arrangement of the redundant bonding regions and facilitating the improvement in the resolution of the display panel 001.

In conclusion, referring to FIGS. 24 to 30, the positions of the electrodes of the first light-emitting element 210 in the light-emitting structure 40 may be different from the positions of the electrodes of the second light-emitting element 220 in the light-emitting structure 40. In this manner, when the damaged light-emitting element 20 is repaired, the position of the light-emitting element 20 for repair in the pixel disposition region 1122 is the same as the position of the damaged light-emitting element 20 in the pixel disposition region 1122 before repair, so the position and angle of the light-emitting element 20 for repair do not need adjustment, thereby facilitating the achievement and simplification in automatic repair and improving the repair efficiency. In addition, the positions of the light-emitting elements 20 in the pixel disposition region 1122 are the same before and after repair so that light-emitting elements 20 in different pixel disposition regions 1122 can be adjacent to each other closely, thereby facilitating the improvement in the resolution of the display panel 001.

In another optional embodiment, the position of the first binding electrode 201 of the second light-emitting element 220 in the light-emitting structure 40 is the same as the position of the first binding electrode 201 of the first light-emitting element 210 in the light-emitting structure 40, and the position of the second binding electrode 202 of the second light-emitting element 220 in the light-emitting structure 40 is the same as the position of the second binding electrode 202 of the first light-emitting element 210 in the light-emitting structure 40.

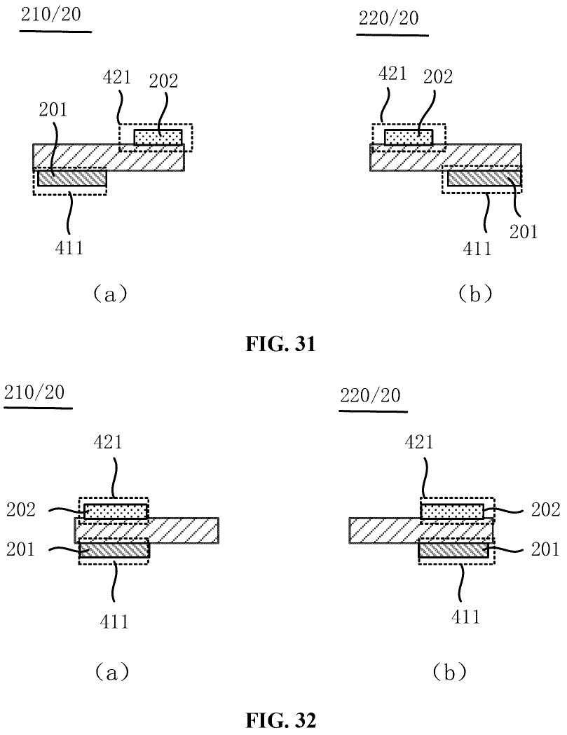

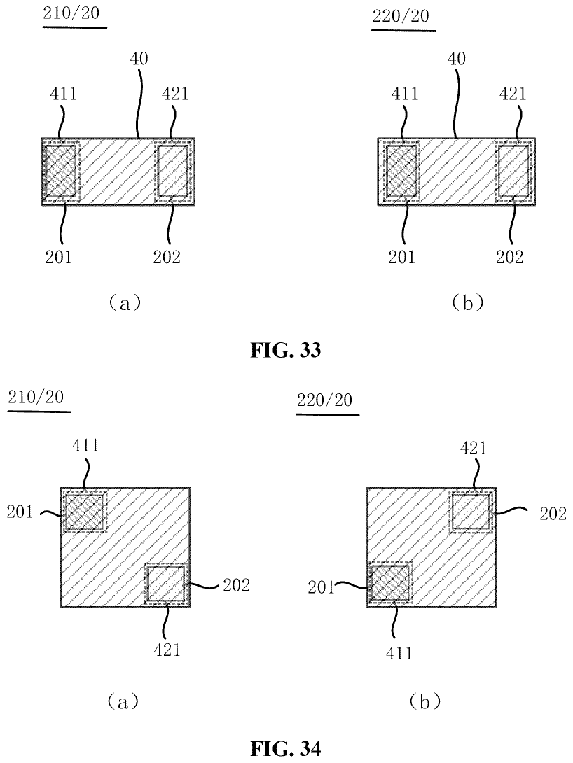

In an exemplary embodiment, FIG. 31 is another cross-section view of a first light-emitting element and a second light-emitting element according to an embodiment of the present disclosure, FIG. 32 is another cross-section view of a first light-emitting element and a second light-emitting element according to an embodiment of the present disclosure, FIG. 33 is another top view of a first light-emitting element and a second light-emitting element according to an embodiment of the present disclosure, and FIG. 34 is another top view of a first light-emitting element and a second light-emitting element according to an embodiment of the present disclosure. The light-emitting elements 20 in FIGS. 31 and 32 may correspond to the display panel 001 and light-emitting elements 20 thereof in FIGS. 3 and 21 or may also correspond to the display panel 001 and light-emitting elements 20 thereof in FIGS. 9 and 23. The light-emitting elements 20 in FIG. 33 correspond to the display panel 001 and light-emitting elements 20 thereof in FIGS. 5, 18 and 22. The light-emitting elements 20 in FIG. 34 correspond to the display panel 001 and light-emitting elements 20 thereof in FIGS. 7 and 20. “Correspond to” only means that the structure types of the light-emitting elements 20 are the same and that the light-emitting elements 20 may be applied to corresponding display panels 001 and does not mean that the structures of corresponding light-emitting elements 20 are exactly the same. In a feasible embodiment, the light-emitting elements 20 in FIGS. 31 to 34 may be different from light-emitting elements 20 in the corresponding display panels 001 in terms of structure.

Referring to FIGS. 31 to 34, the first light-emitting element 210 and the second light-emitting element 220 that are in the same figure may be located in the same display panel 001; in the display panel 001, a light-emitting element 20 is the first light-emitting element 210, and another light-emitting element 20 is the second light-emitting element 220; the first binding electrode 201 of the first light-emitting element 210 and the first binding electrode 201 of the second light-emitting element 220 are located in the first initialization electrode region 411, and the second binding electrode 202 of the first light-emitting element 210 and the second binding electrode 202 of the second light-emitting element 220 are located in the second initialization electrode region 421. Referring to FIGS. 5 to 23, an overlapping region between the projection of the first binding electrode 201 of the first light-emitting element 210 on the plane on which the display panel 001 is located and the projection of the first pad 310 on the plane on which the display panel 001 is located is a first initialization bonding region 311, and an overlapping region between the projection of the second binding electrode 202 of the first light-emitting element 210 on the plane on which the display panel 001 is located and the projection of the second pad 320 on the plane on which the display panel 001 is located is a second initialization bonding region 321. An overlapping region between the projection of the first binding electrode 201 of the second light-emitting element 220 on the plane on which the display panel 001 is located and the projection of the first pad 310 on the plane on which the display panel 001 is located is a first repair bonding region 312, and an overlapping region between the projection of the second binding electrode 202 of the second light-emitting element 220 on the plane on which the display panel 001 is located and the projection of the second pad 320 on the plane on which the display panel 001 is located is a second repair bonding region 322. The first initialization bonding region 311 and the first repair bonding region 312 are different regions, and/or the second initialization bonding region 321 and the second repair bonding region 322 are different regions.

In an embodiment, the positions of the first binding electrode 201 of the first light-emitting element 210 and the second binding electrode 202 of the first light-emitting element 210 in the light-emitting structure 40 are the same as the positions of the first binding electrode 201 of the second light-emitting element 220 and the second binding electrode 202 of the second light-emitting element 220 in the light-emitting structure 40, that is, the first light-emitting element 210 is the same as the second light-emitting element 220. However, a bonding region of the first binding electrode 201 of the first light-emitting element 210 in the first pad 310 is different from a bonding region of the first binding electrode 201 of the second light-emitting element 220 in the first pad 310, and/or a bonding region of the second binding electrode 202 of the first light-emitting element 210 in the second pad 320 is different from a bonding region of the second binding electrode 202 of the second light-emitting element 220 in the second pad 320. In this manner, when the light-emitting element 20 of the display panel 001 is repaired, the damaged light-emitting element 20 and the second light-emitting element 220 for repair are the same light-emitting elements 20, so a light-emitting element for repair does not need designing additionally, thereby facilitating the reduction in the repair cost such as the design cost or the purchasing cost.

It is to be noted that if the damaged light-emitting element 20 and the second light-emitting element 220 for repair are the same light-emitting elements 20, when the light-emitting element 20 of the display panel 001 is repaired, and after the second light-emitting element 220 for repair is transferred to the position above the damaged light-emitting element 20 before repair, the second light-emitting element 220 may need rotation, as shown in FIGS. 31, 32 and 34, or the second light-emitting element 220 may also need movement, as shown in FIGS. 32 and 33, so that the projection of the second light-emitting element 220 for repair on the plane on which the display panel 001 is located cannot completely coincide with the projection of the damaged light-emitting element 20 before repair on the plane on which the display panel 001 is located, but the projection of the second light-emitting element 220 for repair on the plane on which the display panel 001 is located can at least partially overlap the projection of the damaged light-emitting element 20 before repair on the plane on which the display panel 001 is located. Compared with the related art in which the redundant pads are disposed, the display panel 001 provided in the embodiments of the present disclosure can still have high resolution without disposing the redundant pad and redundant pixel disposition region for the light-emitting element 20.

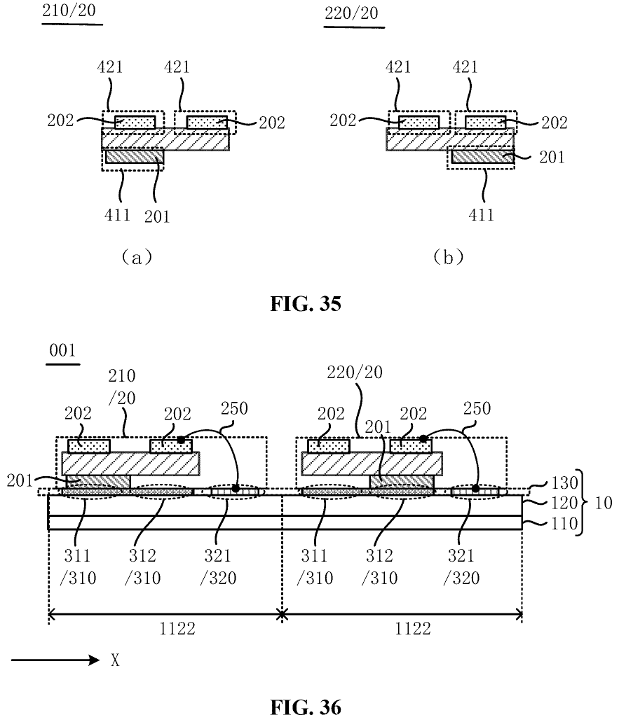

In a feasible embodiment, FIG. 35 is another cross-section view of a first light-emitting element and a second light-emitting element according to an embodiment of the present disclosure, and FIG. 36 is another cross-section view of a display panel according to an embodiment of the present disclosure. Referring to FIGS. 35 and 36, the pixel disposition region 1122 includes the first pad 310 and the second pad 320, and the first binding electrode 201 and the second binding electrode 202 are located on two opposite sides of the light-emitting structure 40. The light-emitting structure 40 includes multiple second initialization electrode regions 421. The light-emitting element 20 includes multiple second binding electrodes 202. The first binding electrode 201 is bonded to the first pad 310. A second binding electrode 202 is electrically connected to the second pad 320 through the lead 250. The first pad 310 and the second pad 320 that are located in the same one pixel disposition region 1122 are arranged in the first direction X parallel to the plane on which the display panel 001 is located. At least some second binding electrodes 202 in the same one light-emitting element 20 are arranged in the first direction X.

Exemplarily, referring to FIGS. 35 and 36, the light-emitting element 20 being the perpendicular structure and the first light-emitting element 210 and the second light-emitting element 220 being the same light-emitting elements 20 is used as an example. When the light-emitting element 20 of the display panel 001 is repaired, the second light-emitting element 220 needs rotation after the second light-emitting element 220 for repair is transferred to the position above the damaged light-emitting element 20 before repair to enable the first binding electrode 201 of the second light-emitting element 220 to be bonded to the first repair bonding region 312 of the first pad 310. Subsequently, among the at least some second binding electrodes 202 arranged in the first direction X, a second binding electrode 202 that is closer to the second pad 320 is connected to the second pad 320 through the lead 250. In this manner, the length of the lead 250 can be reduced, thereby reducing the process complexity. In an embodiment, the at least some second binding electrodes 202 in the same one light-emitting element 20 may also be arranged in the arrangement direction of the first initialization bonding region 311 and the first repair bonding region 312. Details are not repeated herein.

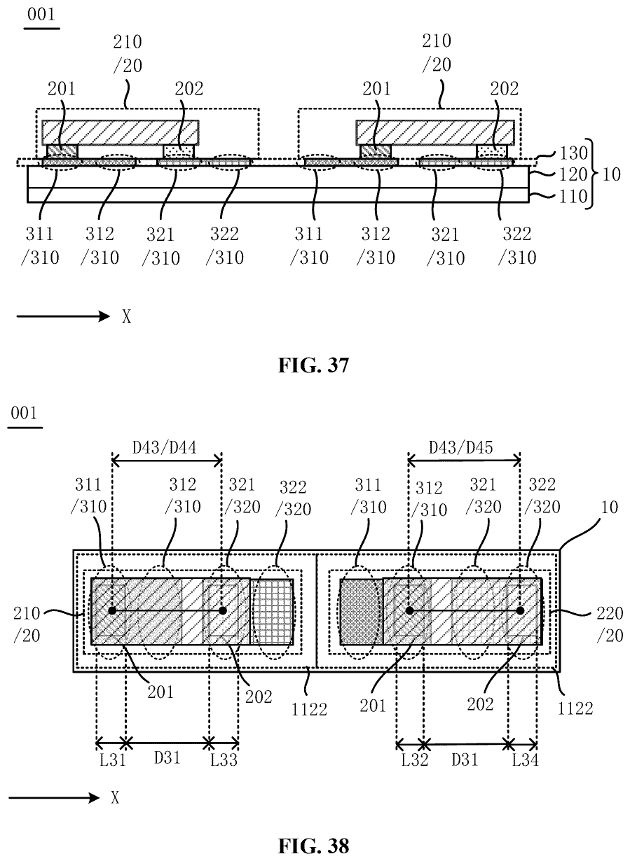

In another feasible embodiment, FIG. 37 is another cross-section view of a display panel according to an embodiment of the present disclosure. Referring to FIG. 37, the pixel disposition region 1122 includes the first pad 310 and the second pad 320, the first binding electrode 201 and the second binding electrode 202 are located on the same side of the light-emitting structure, and the first pad 310 and the second pad 320 that are located in the same one pixel disposition region 1122 are arranged in the first direction X parallel to the plane on which the display panel 001 is located. The first initialization bonding region 311, the first repair bonding region 312, the second initialization bonding region 321 and the second repair bonding region 322 that are located in the same one pixel disposition region 1122 are sequentially arranged in the first direction X, or the first repair bonding region 312, the first initialization bonding region 311, the second repair bonding region 322 and the second initialization bonding region 321 that are located in the same one pixel disposition region 1122 are sequentially arranged in the first direction X.

Exemplarily, the light-emitting element 20 being the inverted structure and the first light-emitting element 210 and the second light-emitting element 220 being the same light-emitting elements 20 is used as an example. When the light-emitting element 20 of the display panel 001 is repaired, the second light-emitting element 220 needs moving in the first direction X after the second light-emitting element 220 for repair is transferred to the position above the damaged light-emitting element 20 before repair to enable the first binding electrode 201 of the second light-emitting element 220 to be bonded to the first repair bonding region 312 of the first pad 310 and the second binding electrode 202 of the second light-emitting element 220 to be bonded to the second repair bonding region 322 of the second pad 320.

Based on the preceding embodiments, FIG. 38 is another top view of a display panel according to an embodiment of the present disclosure. Referring to FIGS. 37 and 38, in the first direction X, the spacing between the first binding electrode 201 and the second binding electrode 202 is the first spacing D31, the length of the first initialization bonding region 311 is the first length L31, the length of the first repair bonding region 312 is the second length L32, the length of the second initialization bonding region 321 is the third length L33, and the length of the second repair bonding region 322 is the fourth length L34. The first spacing D31 is greater than the second length L32 and the third length L33, or the first spacing D31 is greater than the first length L31 and the fourth length L34. It is to be understood that the projections of the bonding regions in the pixel disposition region 1122 on the plane on which the display panel 001 is located coincide with the projections of the binding electrodes of the light-emitting element 20 on the plane on which the display panel 001 is located respectively, the first length L31 and the second length L32 is the length L11 of the first binding electrode 201 in the first direction X, and the third length L33 and the fourth length L34 are the length L21 of the second binding electrode 202 in the first direction X.

In an embodiment, when the light-emitting element 20 is the inverted structure, and the first light-emitting element 210 and the second light-emitting element 220 are the same, the first spacing D31 between the first binding electrode 201 of the light-emitting element 20 and the second binding electrode 202 of the light-emitting element 20 is greater than the length L11 of the first binding electrode 201 in the first direction X, and the length of the first spacing D31 is greater than the length L21 of the second binding electrode 202 in the first direction X. In this manner, after the light-emitting element 20 of the display panel 001 is repaired, the first binding electrode 201 of the light-emitting element 20 and the second binding electrode 202 of the light-emitting element 20 can be bonded to regions of the pads of the pixel disposition region 1122 in which the electrodes are not left, or the connection electrodes are not damaged, so as to prevent the first binding electrode 201 of the second light-emitting element 220 and/or the second binding electrode 202 of the second light-emitting element 220 from being bonded to regions in which the electrodes are left, or the connection electrodes are damaged. Therefore, the bonding effect and repair effect can be ensured, and the second light-emitting element 220 for repair is the same as the first light-emitting element 210 so that the repair cost can be reduced.

Based on the preceding embodiments, with continued reference to FIGS. 37 and 38, at least part of the projection of the second repair bonding region 322 on the plane on which the display panel 001 is located and/or at least part of the projection of the first initialization bonding region 311 on the plane on which the display panel 001 is located are not covered by the projection of the light-emitting element 20 on the plane on which the display panel 001 is located, or at least part of the projection of the first repair bonding region 312 on the plane on which the display panel 001 is located and/or at least part of the projection of the second initialization bonding region 321 on the plane on which the display panel 001 is located are not covered by the projection of the light-emitting element 20 on the plane on which the display panel 001 is located.

Exemplarily, at least part of the projection of the first repair bonding region 312 of the first pad 310 on the plane on which the display panel 001 is located and at least part of the projection of the second repair bonding region 322 of the second pad 320 on the plane on which the display panel 001 is located are not covered by the projection of the first light-emitting element 210 on the plane on which the display panel 001 is located, and at least part of the projection of the first initialization bonding region 311 of the first pad 310 on the plane on which the display panel 001 is located and at least part of the projection of the second initialization bonding region 321 of the second pad 320 on the plane on which the display panel 001 is located are not covered by the projection of the second light-emitting element 220 on the plane on which the display panel 001 is located, that is, the length of the light-emitting element 20 in the first direction X is less than the length of the pixel disposition region 1122 in the first direction X. After the second light-emitting element 220 for repair is transferred to the position above the damaged light-emitting element 20 before repair, the second light-emitting element 220 needs moving in the first direction X. The length of the light-emitting element 20 in the first direction X is small so that a collision between the second light-emitting element 220 and an adjacent light-emitting element 20 can be avoided, where the collision is caused by the deviation of the position in which the second light-emitting element 220 for repair is located from the position in which the damaged light-emitting element 20 before repair is located.

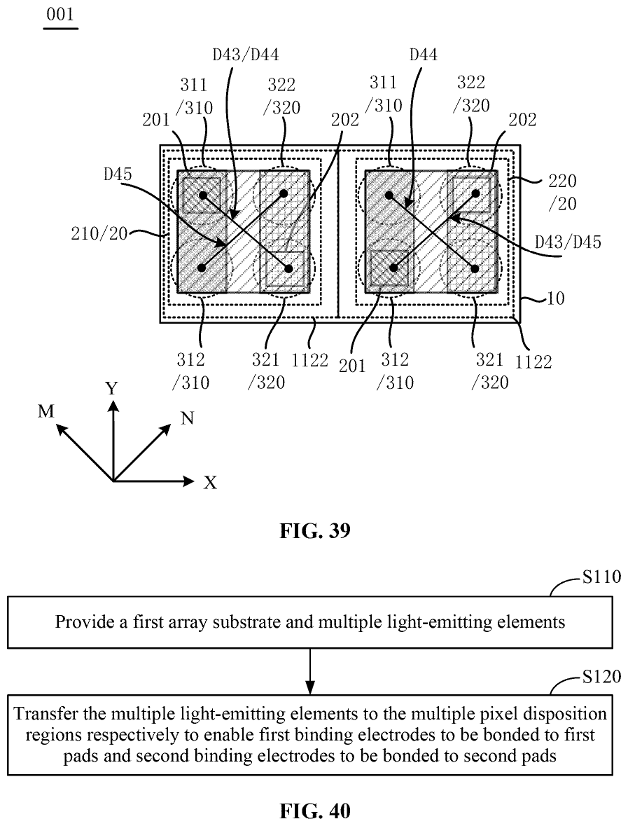

In another exemplary embodiment, FIG. 39 is another top view of a display panel according to an embodiment of the present disclosure. Referring to FIG. 39, the pixel disposition region 1122 includes the first pad 310 and the second pad 320, the first binding electrode 201 and the second binding electrode 202 are located on the same side of the light-emitting structure 40, the arrangement direction of the first initialization bonding region 311 and the second initialization bonding region 321 that are located in the same one pixel disposition region 1122 is the third direction M, and the arrangement direction of the first repair bonding region 312 and the second repair bonding region 322 that are located in the same one pixel disposition region 1122 is the fourth direction N; the third direction M and the fourth direction N are parallel to the plane on which the display panel 001 is located, and the third direction M intersects the fourth direction N.

Exemplarily, the light-emitting element 20 being the inverted structure and the first light-emitting element 210 and the second light-emitting element 220 being the same light-emitting elements 20 is used as an example. When the light-emitting element 20 of the display panel 001 is repaired, the second light-emitting element 220 needs rotating after the second light-emitting element 220 for repair is transferred to the position above the damaged light-emitting element 20 before repair to enable the first binding electrode 201 of the second light-emitting element 220 to be bonded to the first repair bonding region 312 of the first pad 310 and the second binding electrode 202 of the second light-emitting element 220 to be bonded to the second repair bonding region 322 of the second pad 320.

In a feasible embodiment, with continued reference to FIG. 39, the first pad 310 and the second pad 320 that are located in the same one pixel disposition region 1122 are arranged in the first direction X, and the first initialization bonding region 311 and the first repair bonding region 312 that are located in the same one pixel disposition region 1122 are arranged in the second direction Y; the first direction X and the second direction Y are parallel to the plane on which the display panel 001 is located. It is to be understood that the second initialization bonding region 321 and the second repair bonding region 322 that are located in the same one pixel disposition region 1122 are also arranged in the second direction Y intersecting the first direction X. The length of the first light-emitting element 210 in the first direction X is equal to the length of the second light-emitting element 220 in the first direction X. The length of the first light-emitting element 210 in the second direction Y is equal to the length of the second light-emitting element 220 in the second direction Y. In this manner, the lengths of the unrepaired first light-emitting element 210 and the repaired second light-emitting element 220 in the first direction X may be the same, and the lengths of the unrepaired first light-emitting element 210 and the repaired second light-emitting element 220 in the second direction Y may also be the same so that the collision between the second light-emitting element 220 and the adjacent light-emitting element 20 can be avoided, where the collision is caused by the deviation of the position in which the second light-emitting element 220 for repair is located from the position in which the damaged light-emitting element 20 before repair is located.

In an embodiment, an included angle between the third direction M and the fourth direction Nis 90°, and the projection of the light-emitting element 20 on the plane on which the display panel 001 is located has a shape with equal lengths in two mutually perpendicular directions, such as a square, a regular octagon, or a circle.

Based on the preceding embodiments, referring to FIGS. 38 and 39, the spacing between the center of the first binding electrode 201 and the center of the second binding electrode 202 is the third spacing D43, the spacing between the center of the first initialization bonding region 311 and the center of the second initialization bonding region 321 is the fourth spacing D44, and the spacing between the center of the first repair bonding region 312 and the center of the second repair bonding region 322 is the fifth spacing D45; the third spacing D43 is equal to each of the fourth spacing D44 and the fifth spacing D45. In this manner, the first binding electrode 201 of the unrepaired first light-emitting element 210 can be bonded in the first initialization bonding region 311 of the first pad 310, the second binding electrode 202 of the unrepaired first light-emitting element 210 can be bonded in the second initialization bonding region 321 of the second pad 320, the first binding electrode 201 of the repaired second light-emitting element 220 can be bonded in the first repair bonding region 312 of the first pad 310, and the second binding electrode 202 of the repaired second light-emitting element 220 can be bonded in the second repair bonding region 322 of the second pad 320. The third spacing D43 between the binding electrodes of the first light-emitting element 210 is equal to the third spacing D43 between the binding electrodes of the second light-emitting element 220. Therefore, the second light-emitting element 220 for repair does not need designing additionally so that the repair cost can be reduced effectively.

In conclusion, referring to FIGS. 31 to 39, the positions of the electrodes of the first light-emitting element 210 in the light-emitting structure 40 may be the same as the positions of the electrodes of the second light-emitting element 220 in the light-emitting structure 40. In this manner, the light-emitting element for repair does not need designing additionally, thereby facilitating the reduction in the repair cost such as the design cost or the purchasing cost. In addition, the projection of the second light-emitting element 220 for repair on the plane on which the display panel 001 is located at least partially overlaps the projection of the damaged light-emitting element 20 before repair on the plane on which the display panel 001 is located. Compared with the related art in which the redundant pads are disposed, the display panel 001 provided in the embodiments of the present disclosure can still have high resolution without disposing the redundant pad and redundant pixel disposition region for the light-emitting element 20.

Based on the same inventive concept, embodiments of the present disclosure further provide a method for preparing a display panel. FIG. 40 is a flowchart of a method for preparing a display panel according to an embodiment of the present disclosure. Referring to FIG. 40, the method for preparing a display panel includes the steps below.

In S110, a first array substrate and multiple light-emitting elements are provided.

The first array substrate 10 includes multiple pixel disposition regions 1122 corresponding to the multiple light-emitting elements 20 respectively. A pixel disposition region 1122 includes a first pad 310 and/or a second pad 320. The area of the projection of the first pad 310 on the plane on which the display panel 001 is located is greater than or equal to N times the area of the projection of a first binding electrode 201 on the plane on which the display panel 001 is located, and/or the area of the projection of the second pad 320 on the plane on which the display panel 001 is located is greater than or equal to N times the area of the projection of a second binding electrode 202 on the plane on which the display panel 001 is located, where N≥ 2. The provided first array substrate 10 is, for example, the first array substrate 10 in the display panel 001 shown in FIGS. 3 to 10. A light-emitting element 20 includes the first binding electrode 201 and the second binding electrode 202. For example, the provided light-emitting element 20 is the first light-emitting element 210 shown in FIGS. 24 to 28 and 31 to 35.

Exemplarily, the first array substrate 10 includes a base substrate 110, a circuit layer 120 and a conductive layer 130 located on the surface of one side of the circuit layer 120 facing away from the base substrate 110. The conductive layer 130 includes first pads 310 and/or second pads 320. The base substrate 110 may be a rigid substrate or a flexible substrate, which is not specifically limited in this embodiment. The circuit layer 120 includes pixel driving circuits (which are not shown in the figure). The pixel driving circuits are electrically connected to the first pads 310 of the conductive layer 130 or the second pads 320 of the conductive layer 130. The pixel driving circuits are electrically connected to the multiple light-emitting elements 20 through the first pads 310 or the second pads 320 and can drive the multiple light-emitting elements 20 to emit light.

In S120, the multiple light-emitting elements are transferred to the multiple pixel disposition regions respectively to enable first binding electrodes to be bonded to first pads and second binding electrodes to be bonded to second pads.

Exemplarily, the multiple first light-emitting elements 210 are transferred to the multiple pixel disposition regions 1122 respectively using a batch transfer technique. The first binding electrodes 201 and/or the second binding electrodes 202 are bonded to the first pads 310 of the multiple pixel position regions 1122 and/or the second pads 320 of the multiple pixel disposition regions 1122. For the first light-emitting element 210 having a large size and being a perpendicular structure, the first binding electrode 201 of the light-emitting element 20 is bonded to the first pad 310, and the second binding electrode 202 of the light-emitting element 20 may be electrically connected to the second pad 320 through a lead 250. For the first light-emitting element 210 being an inverted structure, the first array substrate 10 includes the first pad 310 and the second pad 320; the first binding electrode 201 of the light-emitting element 20 is bonded to the first pad 310, and the second binding electrode 202 of the light-emitting element 20 may be bonded to the second pad 320. For the first light-emitting element 210 having a small size and being the perpendicular structure, a second substrate 50 may also be provided, the first array substrate 10 includes the first pad 310, and the second substrate 50 includes the second pad 320; or the first array substrate 10 may also include the second pad 320, and the second substrate 50 may also include the first pad 310; the light-emitting element 20 is located between the first array substrate 10 and the second substrate 50, the first binding electrode 201 of the light-emitting element 20 is bonded to the first pad 310, and the second binding electrode 202 of the light-emitting element 20 is bonded to the second pad 320. The area of the projection of the first pad 310 on the plane on which the display panel 001 is located and/or the area of the projection of the second pad 320 on the plane on which the display panel 001 is located are large, and/or the areas of the projections of the binding electrodes on the plane on which the display panel is located are small so that the area of the projection of the first pad on the plane on which the display panel is located can be two or more than two times the area of the projection of the first binding electrode on the plane on which the display panel is located, and/or the area of the projection of the second pad on the plane on which the display panel is located can be two or more than two times the area of the projection of the second binding electrode on the plane on which the display panel is located, thereby reducing the alignment difficulty of the light-emitting element 20 and improving the binding yield. In this case, the display panel 001 has not been repaired, and all the light-emitting elements 20 on the display panel 001 are first light-emitting elements 210.

In an optional embodiment, that the multiple light-emitting elements are transferred to the multiple pixel disposition regions respectively to enable the first binding electrodes to be bonded to the first pads and the second binding electrodes to be bonded to the second pads includes that the multiple light-emitting elements are transferred to preset positions above the multiple pixel disposition regions respectively to enable first binding electrodes of light-emitting elements to be bonded to the first pads of first pixel disposition regions and/or second binding electrodes of the light-emitting elements to be bonded to the second pads of the first pixel disposition regions.

The preset positions are located above the multiple pixel disposition regions and are a first height away from the first array substrate. After being transferred to the preset positions, the multiple light-emitting elements may be moved in the perpendicular direction of the plane on which the first array substrate is located and are bonded to the pads in the multiple pixel disposition regions. The movement of the multiple light-emitting elements in the perpendicular direction of the plane on which the first array substrate is located may be a free fall motion or may also be achieved using an automatic mechanical apparatus, which is not limited in the embodiments of the present disclosure.

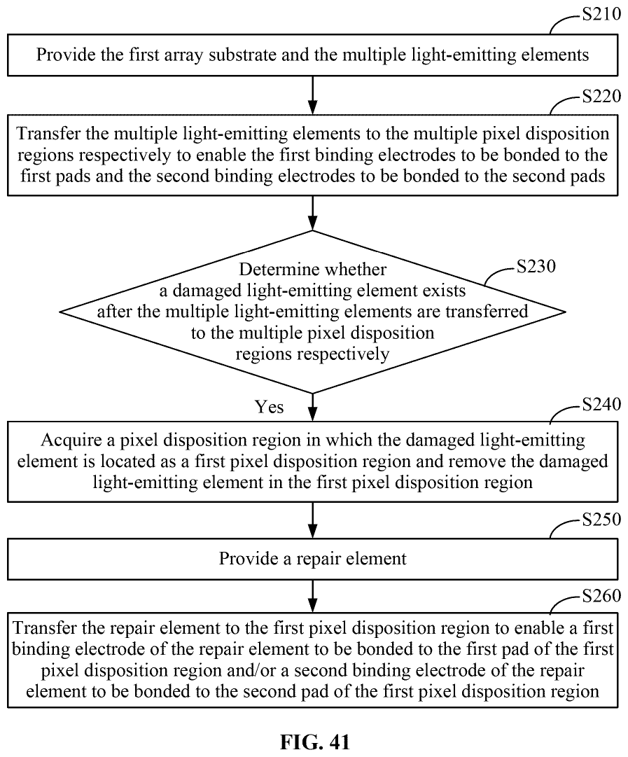

Optionally, FIG. 41 is another flowchart of a method for preparing a display panel according to an embodiment of the present disclosure. Referring to FIG. 41, the method for preparing a display panel includes the steps below.

In S210, the first array substrate and the multiple light-emitting elements are provided.

In S220, the multiple light-emitting elements are transferred to the multiple pixel disposition regions respectively to enable the first binding electrodes to be bonded to the first pads and the second binding electrodes to be bonded to the second pads.

In S230, whether a damaged light-emitting element exists is determined after the multiple light-emitting elements are transferred to the multiple pixel disposition regions respectively; if yes, S240 is executed.

In S240, a pixel disposition region in which the damaged light-emitting element is located is acquired as a first pixel disposition region, and the damaged light-emitting element in the first pixel disposition region is removed.

In S250, a repair element is provided.

The repair element is a to-be-transferred light-emitting element 20 and is configured to replace the damaged light-emitting element 20. The provided repair element is, for example, the second light-emitting element 220 shown in FIGS. 24 to 28 and 31 to 35.

In S260, the repair element is transferred to the first pixel disposition region to enable a first binding electrode of the repair element to be bonded to the first pad of the first pixel disposition region and/or a second binding electrode of the repair element to be bonded to the second pad of the first pixel disposition region.

A bonding region between the first binding electrode 201 of the damaged light-emitting element 20 and the first pad 310 is a first initialization bonding region 311; a bonding region between the second binding electrode 202 of the damaged light-emitting element 20 and the second pad 320 is a second initialization bonding region 321; a bonding region between the first binding electrode 201 of the repair element and the first pad 310 is a first repair bonding region 312; and/or a bonding region between the second binding region 202 of the repair element and the second pad 320 is a second repair bonding region 322. The first initialization bonding region 311 and the first repair bonding region 312 are different regions, and the second initialization bonding region 321 and the second repair bonding region 322 are different regions.

Exemplarily, after all the multiple first light-emitting elements 210 are transferred to the multiple pixel disposition regions 1122 respectively, if no damaged first light-emitting element 210 exists, this indicates that the display panel 001 is non-defective, so the processing procedure such as packaging may continue; if a damaged first light-emitting element 210 exists, this indicates that the display panel 001 has a defective light-emitting element 20, so the light-emitting element 20 needs repairing, and the processing procedure such as the packaging continues after the repair is finished.

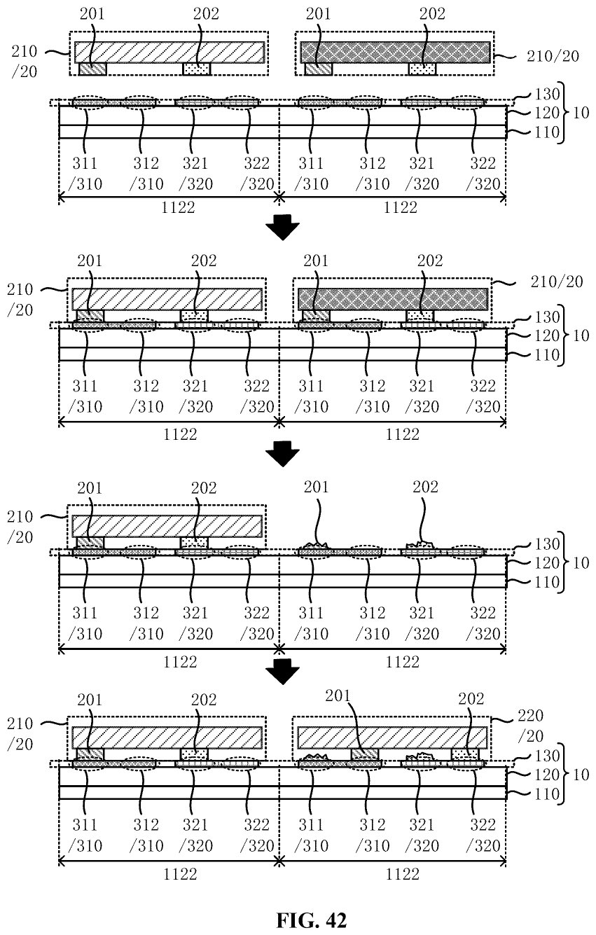

The light-emitting element 20 being an inverted structure is used as an example to illustrate the repair process. In this case, the first array substrate 10 including the first pad 310 and the second pad 320. FIG. 42 is a diagram illustrating the structure of a process for preparing a display panel according to an embodiment of the present disclosure. Referring to FIG. 42, if present, the damaged first light-emitting element 210 needs removing. In the process of removing the damaged first light-emitting element 210, the first binding electrode 201 of the first light-emitting element 210 and/or the second binding electrode 202 of the first light-emitting element 210 may be partially left, that is, the first initialization bonding region 311 may be left with part of the first binding electrode 201, and/or the second initialization bonding region 321 may be left with part of the second binding electrode 202, but the residual first binding electrode 201 and/or the residual second binding electrode 202 do not need processing, and the second light-emitting element 220 for repair may be directly transferred to the first pixel disposition region in which the damaged first light-emitting element 210 is located. The first binding electrode 201 of the second light-emitting element 220 may be bonded to the first pad 310 of the first repair bonding region 312 located outside the first initialization bonding region 311, and the second binding electrode 202 of the second light-emitting element 220 may be bonded to the second pad 320 of the second repair bonding region 322 located outside the second initialization bonding region 321. In this manner, the repair difficulty can be reduced. Moreover, the second light-emitting element 220 for repair can also be placed in the position of the originally damaged first light-emitting element 210 for replacement, without disposing the redundant pad and the redundant pixel disposition region, so that the impact of repairing the light-emitting element on the resolution can be reduced effectively, thereby facilitating the improvement in the yield and display effect of the display panel 001.

In an optional embodiment, the light-emitting element 20 includes a light-emitting structure 40, and the regions of the first binding electrode 201 of the damaged light-emitting element 20 and the second binding electrode 202 of the damaged light-emitting element 20 in the light-emitting structure 40 are different from the regions of the first binding electrode 201 of the repair element and the second binding electrode 202 of the repair element in the light-emitting structure 40. The damaged light-emitting element 20 is, for example, the first light-emitting element 210 shown in FIGS. 24 to 27, and the repair element is, for example, the second light-emitting element 220 shown in FIGS. 24 to 27.

That the repair element is transferred to the first pixel disposition region to enable the first binding electrode of the repair element to be bonded to the first pad of the first pixel disposition region and/or the second binding electrode of the repair element to be bonded to the second pad of the first pixel disposition region includes that the repair element is transferred to a first preset position above the first pixel disposition region to enable the first binding electrode of the repair element to be bonded to the first pad of the first pixel disposition region and/or the second binding electrode of the repair element to be bonded to the second pad of the first pixel disposition region. The first pixel disposition region is one of the multiple pixel disposition regions and refers to a region in which the damaged light-emitting element 20 has been present. The first preset position is one of the preset positions. The first preset position is located above the first pixel disposition region and is a first height away from the first array substrate. After being transferred to the first preset position, the repair element may be moved in the perpendicular direction of the plane on which the first array substrate is located and is bonded to the pads in the first pixel disposition region. The movement of the repair element in the perpendicular direction of the plane on which the first array substrate is located may be a free fall motion or may also be achieved using an automatic mechanical apparatus, which is not limited in the embodiments of the present disclosure.

In an embodiment, the positions of the first binding electrode of the repair element and the second binding electrode of the repair element in the light-emitting structure are different from the positions of the first binding electrode of the damaged light-emitting element and the second binding electrode of the damaged light-emitting element in the light-emitting structure; when the damaged light-emitting element is repaired, and after the repair element is transferred to the first preset position, the repair element is moved in the perpendicular direction of the plane on which the first array substrate is located so that the position of the repair element in the first pixel disposition region can be the same as the position of the damaged light-emitting element before repair in the first pixel disposition region. Therefore, without adjusting the position and angle of the repair element, the bonding regions of the binding electrodes of the repair element in the pads can be different from the bonding regions of the binding electrodes of the damaged light-emitting element in the pads, thereby facilitating the achievement and simplification in automatic repair and improving the repair efficiency. In addition, the positions of the light-emitting elements in the pixel disposition region are the same before and after repair so that light-emitting elements in different pixel disposition regions can be adjacent to each other closely, thereby facilitating the improvement in the resolution of the display panel.

In an optional embodiment, the light-emitting element 20 includes the light-emitting structure 40, the regions of the first binding electrode 201 of the damaged light-emitting element 20 and the second binding electrode 202 of the damaged light-emitting element 20 in the light-emitting structure 40 are the same as the regions of the first binding electrode 201 of the repair element and the second binding electrode 202 of the repair element in the light-emitting structure 40, and the first binding electrodes 201 and the second binding electrodes 202 are located on the same side of the light-emitting structure 40. The damaged light-emitting element 20 is, for example, the first light-emitting element 210 shown in FIG. 33, and the repair element is, for example, the second light-emitting element 220 shown in FIG. 33. The pixel disposition region 1122 includes the first pad 310 and the second pad 320. The first pad 310 and the second pad 320 that are located in the same one pixel disposition region 1122 are arranged in the first direction X parallel to the plane on which the display panel 001 is located. The first initialization bonding region 311 and the first repair bonding region 312 that are located in the same one first pad 310 and the second initialization bonding region 321 and the second repair bonding region 322 that are located in the same one second pad 320 are arranged in the first direction X. The pixel disposition region 1122 is, for example, the pixel disposition region 1122 shown in FIGS. 37 and 38.

That the repair element is transferred to the first pixel disposition region to enable the first binding electrode of the repair element to be bonded to the first pad of the first pixel disposition region and/or the second binding electrode of the repair element to be bonded to the second pad of the first pixel disposition region includes that the repair element is transferred to the first preset position above the first pixel disposition region, and the repair element is moved in the first direction by a first movement distance with the first preset position as the starting point to enable the first binding electrode of the repair element to be bonded to the first pad of the first pixel disposition region and the second binding electrode of the repair element to be bonded to the second pad of the first pixel disposition region. The first movement distance is the distance from the center of the first initialization bonding region to the center of the first repair bonding region, where the first initialization bonding region and the first repair bonding region are located in the same one first pad or the distance from the center of the second initialization bonding region to the center of the second repair bonding region, where the second initialization bonding region and the second repair bonding region are located in the same one second pad.

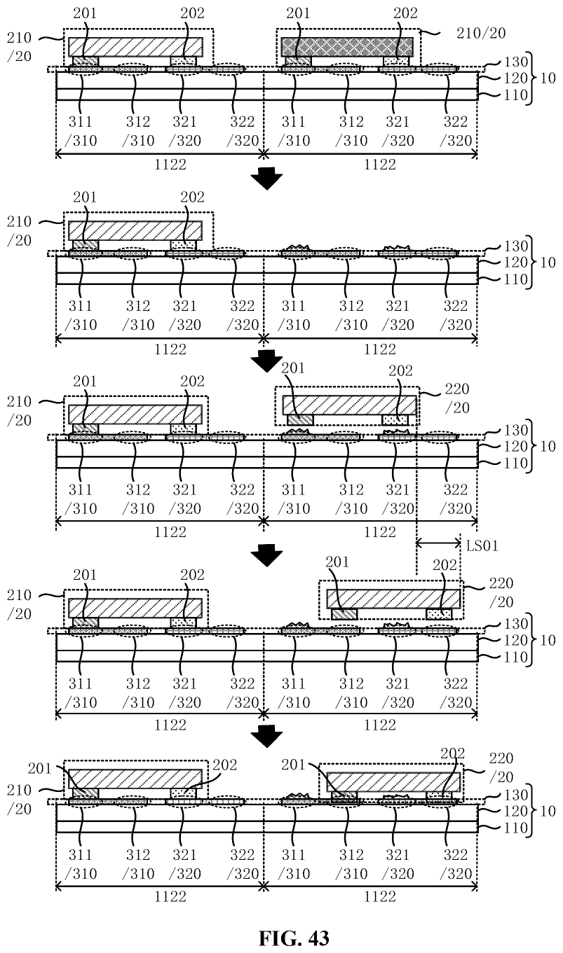

Exemplarily, FIG. 43 is another diagram illustrating structures in a process for preparing a display panel according to an embodiment of the present disclosure. Referring to FIG. 43, after being transferred to the first preset position above the first pixel disposition region, the repair element is moved in the first direction X by the first movement distance LS01, then is moved in the perpendicular direction of the plane on which the first array substrate 10 is located and is bonded to the pads of the first repair bonding region 312 and the second repair bonding region 322 in the first pixel disposition region.

In another optional embodiment, the light-emitting element 20 of the display panel includes the light-emitting structure 40, the regions of the first binding electrode 201 of the damaged light-emitting element 20 and the second binding electrode 202 of the damaged light-emitting element 20 in the light-emitting structure 40 are the same as the regions of the first binding electrode 201 of the repair element and the second binding electrode 202 of the repair element in the light-emitting structure 40, and the first binding electrodes 201 and the second binding electrodes 202 are located on the same side of the light-emitting structure 40. The damaged light-emitting element 20 is, for example, the first light-emitting element 210 shown in FIG. 34, and the repair element is, for example, the second light-emitting element 220 shown in FIG. 34. The pixel disposition region 1122 includes the first pad 310 and the second pad 320; the arrangement direction of the first initialization bonding region 311 and the second initialization bonding region 321 that are located in the same one pixel disposition region 1122 is the third direction M, and the arrangement direction of the first repair bonding region 312 and the second repair bonding region 322 that are located in the same one pixel disposition region 1122 is the fourth direction N; the third direction M and the fourth direction N are parallel to the plane on which the display panel 001 is located, and the third direction M intersects the fourth direction N. The pixel disposition region 1122 is, for example, the pixel disposition region 1122 shown in FIG. 39.

That the repair element is transferred to the first pixel disposition region to enable the first binding electrode of the repair element to be bonded to the first pad of the first pixel disposition region and/or the second binding electrode of the repair element to be bonded to the second pad of the first pixel disposition region includes that the repair element is transferred to the first preset position above the first pixel disposition region, and the repair element is rotated by a first angle with the first preset position as the starting point and the center of the repair element as the rotation shaft to enable the first binding electrode of the repair element to be bonded to the first pad of the first pixel disposition region and the second binding electrode of the repair element to be bonded to the second pad of the first pixel disposition region, where the first angle is an included angle between the third direction and the fourth direction and is less than or equal to 90°.

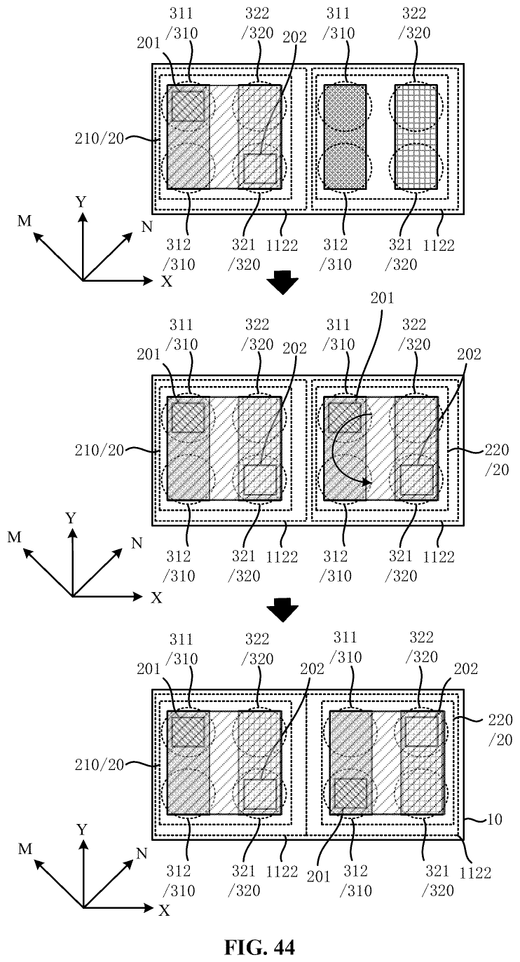

Exemplarily, FIG. 44 is another diagram illustrating structures in a process for preparing a display panel according to an embodiment of the present disclosure. Referring to FIG. 44, after being transferred to the first preset position above the first pixel disposition region, the repair element is rotated in the arrangement direction of the first initialization bonding region 311 and the first repair bonding region 312 by the first angle, then is moved in the perpendicular direction of the plane on which the first array substrate 10 is located and is bonded to the pads of the first repair bonding region 312 and the second repair bonding region 322 in the first pixel disposition region.

The method for preparing a display panel provided in the embodiments of the present disclosure is to prepare the display panel provided in any embodiment of the present disclosure and has the technical features and beneficial effects that correspond to the display panel. For the content not described in detail in the embodiments of the method for preparing a display panel, references may be made to the preceding description of the display panel. Details are not repeated herein. Similarly, the display panel provided in the embodiments of the present disclosure also has the functional modules and beneficial effects that can perform the method for preparing a display panel provided in the embodiments of the present disclosure. For the content not described in detail in the embodiments of the display panel, references may be made to the preceding description of the method for preparing a display panel. Details are not repeated herein.

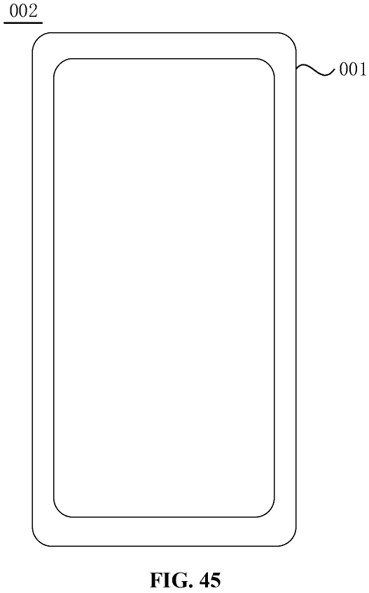

Based on the same inventive concept, embodiments of the present disclosure further provide a display device. FIG. 45 is a diagram illustrating structures in a display device according to an embodiment of the present disclosure. Referring to FIG. 45, the display device 002 includes the display panel 001 provided in any embodiment of the present disclosure. The display device 002 provided in the embodiments of the present disclosure may be a phone shown in FIG. 45, or may be any electronic product having a display function. The electronic product includes, but is not limited to, a television, a laptop, a desktop display, a tablet computer, a digital camera, a smart bracelet, smart glasses, a vehicle-mounted display, a medical device, an industrial control device, or a touch interactive terminal, which is not specially limited in the embodiments of the present disclosure.

It is to be noted that the preceding are preferred embodiments of the present disclosure and technical principles used therein. It is to be understood by those skilled in the art that the present disclosure is not limited to the embodiments described herein. For those skilled in the art, various apparent modifications, adaptations and substitutions can be made without departing from the scope of the present disclosure. Therefore, though the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising a first array substrate and a plurality of light-emitting elements located on one side of the first array substrate, wherein a light-emitting element of the plurality of light-emitting elements comprises a first binding electrode and a second binding electrode;
wherein the first array substrate comprises a plurality of pixel disposition regions corresponding to the plurality of light-emitting elements respectively, wherein a pixel disposition region of the plurality of pixel disposition regions comprises at least one of a first pad or a second pad; the first binding electrode is electrically connected to the first pad; the second binding electrode is electrically connected to the second pad; and
wherein at least one of the following is satisfied: an area of a projection of the first pad on a plane on which the display panel is located is greater than or equal to N times an area of a projection of the first binding electrode on the plane on which the display panel is located, or an area of a projection of the second pad on the plane on which the display panel is located is greater than or equal to N times an area of a projection of the second binding electrode on the plane on which the display panel is located, wherein N≥2.

2. The display panel of claim 1, wherein a projection of the light-emitting element on the plane on which the display panel is located covers at least one of the projection of the first pad on the plane on which the display panel is located or the projection of the second pad on the plane on which the display panel is located.

3. The display panel of claim 1, wherein the first array substrate further comprises at least one of a first connection electrode or a second connection electrode, wherein the first connection electrode is located between the first binding electrode and the first pad, and the second connection electrode is located between the second binding electrode and the second pad; and
at least one of the following is satisfied: the first connection electrode comprises a first eutectic portion and a first connection portion, or the second connection electrode comprises a second eutectic portion and a second connection portion,
wherein at least one of the following is satisfied: a projection of the first eutectic portion on the plane on which the display panel is located overlaps the projection of the first binding electrode on the plane on which the display panel is located, and a projection of the first connection portion on the plane on which the display panel is located does not overlap the projection of the first binding electrode on the plane on which the display panel is located; or a projection of the second eutectic portion on the plane on which the display panel is located overlaps the projection of the second binding electrode on the plane on which the display panel is located, and a projection of the second connection portion on the plane on which the display panel is located does not overlap the projection of the second binding electrode on the plane on which the display panel is located;
wherein a thickness of the first eutectic portion in a perpendicular direction of the plane on which the display panel is located is a first eutectic thickness, a thickness of the first connection portion in the perpendicular direction of the plane on which the display panel is located is a first connection thickness, a thickness of the second eutectic portion in the perpendicular direction of the plane on which the display panel is located is a second eutectic thickness, and a thickness of the second connection portion in the perpendicular direction of the plane on which the display panel is located is a second connection thickness, wherein among at least one pixel disposition region of the plurality of pixel disposition regions, in a same one pixel disposition region, at least one of the following is satisfied: the first connection thickness is greater than or equal to the first eutectic thickness, or the second connection thickness is greater than or equal to the second eutectic thickness; and
wherein among the at least one pixel disposition region, in a same one pixel disposition region, at least one of the following is satisfied: the first connection thickness of part of the first connection portion is less than the first eutectic thickness of the first eutectic portion, or the second connection thickness of part of the second connection portion is less than the second eutectic thickness of the second eutectic portion; or among the at least one pixel disposition region, at least one of the following is satisfied: the first connection portion comprises a first hollow portion, or the second connection portion comprises a second hollow portion; or a pixel disposition region of the at least one pixel disposition region comprises at least one of a first residual electrode or a second residual electrode,
wherein at least one of the following is satisfied: a projection of the first residual electrode on the plane on which the display panel is located overlaps the projection of the first connection portion on the plane on which the display panel is located, or a projection of the second residual electrode on the plane on which the display panel is located overlaps the projection of the second connection portion on the plane on which the display panel is located.

4. The display panel of claim 1, further comprising an adhesive layer, wherein the adhesive layer comprises an adhesive and conductive particles,
wherein the adhesive layer is located between the light-emitting element and the first array substrate;
wherein the adhesive layer comprises a plurality of first adhesive portions and at least one second adhesive portion, wherein a projection of a first adhesive portion of the plurality of first adhesive portions on the plane on which the display panel is located overlaps the projection of the first binding electrode on the plane on which the display panel is located or the projection of the second binding electrode on the plane on which the display panel is located, and a projection of a second adhesive portion of the at least one second adhesive portion on the plane on which the display panel is located does not overlap the projection of the first binding electrode on the plane on which the display panel is located and the projection of the second binding electrode on the plane on which the display panel is located;
wherein a thickness of the first adhesive portion in a perpendicular direction of the plane on which the display panel is located is a first adhesive thickness, and a thickness of the second adhesive portion in the perpendicular direction of the plane on which the display panel is located is a second adhesive thickness, wherein among at least one pixel disposition region of the plurality of pixel disposition regions, in a same one pixel disposition region, the second adhesive thickness is greater than the first adhesive thickness; and
wherein among the at least one pixel disposition region, in a same one pixel disposition region, the second adhesive thickness of part of the second adhesive portion is less than the first adhesive thickness of the first adhesive portion; or among the at least one pixel disposition region, the second adhesive portion comprises a third hollow portion.

5. The display panel of claim 1, wherein at least one of the following is satisfied: the first pad comprises one first initialization bonding region and at least one first repair bonding region, or the second pad comprises one second initialization bonding region and at least one second repair bonding region, wherein the first initialization bonding region and the at least one first repair bonding region are different regions, and the second initialization bonding region and the at least one second repair bonding region are also different regions; and
a light-emitting element of the plurality of light-emitting elements is a first light-emitting element, wherein the first binding electrode of the first light-emitting element is bonded to the first initialization bonding region of the first pad, and the second binding electrode of the first light-emitting element is bonded to the second initialization bonding region of the second pad.

6. The display panel of claim 5, wherein the pixel disposition region comprises the first pad and the second pad; the first pad comprises the one first initialization bonding region and the at least one first repair bonding region, and the second pad comprises the one second initialization bonding region and the at least one second repair bonding region; and
a connection line between a center of the first initialization bonding region and a center of the second initialization bonding region is a first connection line, wherein the first initialization bonding region and the second initialization bonding region are located in a same one pixel disposition region among the plurality of pixel disposition regions, and a connection line between a center of a first repair bonding region of the at least one first repair bonding region and a center of a second repair bonding region of the at least one second repair bonding region is a second connection line, wherein the first repair bonding region and the second repair bonding region are located in the same one pixel disposition region; wherein the first connection line overlaps the second connection line.

7. The display panel of claim 5, wherein at least one of the following is satisfied: another light-emitting element of the plurality of light-emitting elements is a second light-emitting element, wherein the first binding electrode of the second light-emitting element is bonded to the first repair bonding region of the first pad, or the second binding electrode of the second light-emitting element is bonded to the second repair bonding region of the second pad; and
at least one of the following is satisfied: a projection of the second light-emitting element on the plane on which the display panel is located overlaps a projection of the first initialization bonding region on the plane on which the display panel is located, or the projection of the second light-emitting element on the plane on which the display panel is located overlaps a projection of the second initialization bonding region on the plane on which the display panel is located.

8. The display panel of claim 1, wherein the pixel disposition region comprises a first edge in an arrangement direction of the first pad and the second pad and close to the first pad and further comprises a second edge adjacent to the first edge; and
the plurality of light-emitting elements comprise a first light-emitting element and a second light-emitting element, wherein a distance from the first binding electrode of the first light-emitting element to the first edge is a first distance, a distance from the first binding electrode of the second light-emitting element to the first edge is a second distance, a distance from the second binding electrode of the first light-emitting element to the second edge is a third distance, and a distance from the second binding electrode of the second light-emitting element to the second edge is a fourth distance,
wherein at least one of the following is satisfied: the first distance is not equal to the second distance, or the third distance is not equal to the fourth distance.

9. The display panel of claim 8, wherein the arrangement direction of the first pad and the second pad is a first direction, and a second direction intersects the first direction,
wherein at least one of the following is satisfied: an absolute value of a difference between the second distance and the first distance is greater than a length of the first binding electrode in the first direction, or an absolute value of a difference between the fourth distance and the third distance is greater than a length of the second binding electrode in the second direction.

10. The display panel of claim 1, wherein the light-emitting element comprises a light-emitting structure, wherein the light-emitting structure comprises a first initialization electrode region and a second initialization electrode region; and
a light-emitting element of the plurality of light-emitting elements is a first light-emitting element, wherein the first binding electrode of the first light-emitting element is located in the first initialization electrode region, and the second binding electrode of the first light-emitting element is located in the second initialization electrode region.

11. The display panel of claim 10, wherein the light-emitting structure further comprises at least one of the following: at least one first repair electrode region or at least one second repair electrode region; the first initialization electrode region and the at least one first repair electrode region are located on a same side of the light-emitting structure and are different regions; the second initialization electrode region and the at least one second repair electrode region are located on a same side of the light-emitting structure and are different regions; and
another light-emitting element of the plurality of light-emitting elements is a second light-emitting element, wherein at least one of the following is satisfied: the first binding electrode of the second light-emitting element is located in a first repair electrode region of the at least one first repair electrode region, or the second binding electrode of the second light-emitting element is located in a second repair electrode region of the at least one second repair electrode region.

12. The display panel of claim 11,
wherein the first binding electrode of the light-emitting element and the second binding electrode of the light-emitting element are located on two opposite sides of the light-emitting structure respectively, wherein a projection of the first binding electrode of the first light-emitting element on the plane on which the display panel is located does not overlap a projection of the second binding electrode of the first light-emitting element on the plane on which the display panel is located, and a projection of the first binding electrode of the second light-emitting element on the plane on which the display panel is located overlaps a projection of the second binding electrode of the second light-emitting element on the plane on which the display panel is located; or a projection of the first binding electrode of the first light-emitting element on the plane on which the display panel is located overlaps a projection of the second binding electrode of the first light-emitting element on the plane on which the display panel is located, and a projection of the first binding electrode of the second light-emitting element on the plane on which the display panel is located does not overlap a projection of the second binding electrode of the second light-emitting element on the plane on which the display panel is located; or
wherein the pixel disposition region comprises the first pad and the second pad, and the first binding electrode and the second binding electrode are located on two opposite sides of the light-emitting structure;
the light-emitting structure comprises a plurality of second initialization electrode regions, and the light-emitting element comprises a plurality of second binding electrodes; the first binding electrode is bonded to the first pad, and a second binding electrode among the plurality of second binding electrodes is electrically connected to the second pad through a lead; and
the first pad and the second pad that are located in a same one pixel disposition region among the plurality of pixel disposition regions are arranged in a first direction parallel to the plane on which the display panel is located, and at least some of the plurality of second binding electrodes in a same one light-emitting element among the plurality of light-emitting elements are arranged in the first direction.

13. The display panel of claim 1, wherein the plurality of light-emitting elements comprise a first light-emitting element and a second light-emitting element, wherein the first light-emitting element and the second light-emitting element each comprise a light-emitting structure, and the first binding electrode and the second binding electrode are located in the light-emitting structure;
a projection of the first binding electrode of the first light-emitting element on the plane on which the display panel is located and a projection of the second binding electrode of the first light-emitting element on the plane on which the display panel is located are arranged in a first direction parallel to the plane on which the display panel is located;
the light-emitting structure comprises a third edge and a fourth edge that are arranged in the first direction; in a same one pixel disposition region among the plurality of pixel disposition regions,
the third edge is close to the first binding electrode of the first light-emitting element, and the fourth edge is close to the second binding electrode of the first light-emitting element; and
in the same one pixel disposition region, a distance from the first binding electrode of the first light-emitting element to the third edge is a fifth distance, a distance from the first binding electrode of the second light-emitting element to the third edge is a sixth distance, a distance from the second binding electrode of the first light-emitting element to the fourth edge is a seventh distance, and a distance from the second binding electrode of the second light-emitting element to the fourth edge is an eight distance,
wherein at least one of the following is satisfied: the fifth distance is not equal to the sixth distance, or the seventh distance is not equal to the eighth distance.

14. The display panel of claim 13, wherein at least one of the following is satisfied: an absolute value of a difference between the sixth distance and the fifth distance is greater than a length of the first binding electrode in the first direction, or an absolute value of a difference between the eighth distance and the seventh distance is greater than a length of the second binding electrode in the first direction.

15. The display panel of claim 10, wherein another light-emitting element of the plurality of light-emitting elements is a second light-emitting element, wherein the first binding electrode of the second light-emitting element is located in the first initialization electrode region, and the second binding electrode of the second light-emitting element is located in the second initialization electrode region;
an overlapping region between a projection of the first binding electrode of the first light-emitting element on the plane on which the display panel is located and the projection of the first pad on the plane on which the display panel is located is a first initialization bonding region, and an overlapping region between a projection of the second binding electrode of the first light-emitting element on the plane on which the display panel is located and the projection of the second pad on the plane on which the display panel is located is a second initialization bonding region;
an overlapping region between a projection of the first binding electrode of the second light-emitting element on the plane on which the display panel is located and the projection of the first pad on the plane on which the display panel is located is a first repair bonding region, and an overlapping region between a projection of the second binding electrode of the second light-emitting element on the plane on which the display panel is located and the projection of the second pad on the plane on which the display panel is located is a second repair bonding region; and;
at least one of the following is satisfied: the first initialization bonding region and the first repair bonding region are different regions, or the second initialization bonding region and the second repair bonding region are different regions.

16. The display panel of claim 15, wherein the pixel disposition region comprises the first pad and the second pad, and the first binding electrode and the second binding electrode are located on a same side of the light-emitting structure; the first pad and the second pad that are located in a same one pixel disposition region among the plurality of pixel disposition regions are arranged in a first direction parallel to the plane on which the display panel is located; and
the first initialization bonding region, the first repair bonding region, the second initialization bonding region and the second repair bonding region that are located in the same one pixel disposition region are sequentially arranged in the first direction, or the first repair bonding region, the first initialization bonding region, the second repair bonding region and the second initialization bonding region that are located in the same one pixel disposition region are sequentially arranged in the first direction.

17. The display panel of claim 16,
wherein in the first direction, a spacing between the first binding electrode and the second binding electrode is a first spacing, a length of the first initialization bonding region is a first length, a length of the first repair bonding region is a second length, a length of the second initialization bonding region is a third length, and a length of the second repair bonding region is a fourth length; and the first spacing is greater than the second length and the third length, or the first spacing is greater than the first length and the fourth length; or
wherein at least one of the following: at least part of a projection of the second repair bonding region on the plane on which the display panel is located or at least part of a projection of the first initialization bonding region on the plane on which the display panel is located are not covered by a projection of the light-emitting element on the plane on which the display panel is located; or at least one of the following: at least part of a projection of the first repair bonding region on the plane on which the display panel is located or at least part of a projection of the second initialization bonding region on the plane on which the display panel is located are not covered by a projection of the light-emitting element on the plane on which the display panel is located.

18. The display panel of claim 15, wherein the pixel disposition region comprises the first pad and the second pad, and the first binding electrode and the second binding electrode are located on a same side of the light-emitting structure; an arrangement direction of the first initialization bonding region and the second initialization bonding region that are located in a same one pixel disposition region among the plurality of pixel disposition regions is a third direction; an arrangement direction of the first repair bonding region and the second repair bonding region that are located in the same one pixel disposition region is a fourth direction, wherein the third direction and the fourth direction are parallel to the plane on which the display panel is located, and the third direction intersects the fourth direction.

19. The display panel of claim 18,
wherein a spacing between a center of the first binding electrode and a center of the second binding electrode is a third spacing; a spacing between a center of the first initialization bonding region and a center of the second initialization bonding region is a fourth spacing; a spacing between a center of the first repair bonding region and a center of the second repair bonding region is a fifth spacing, wherein the third spacing is equal to each of the fourth spacing and the fifth spacing; or
wherein the first pad and the second pad that are located in the same one pixel disposition region are arranged in a first direction; the first initialization bonding region and the first repair bonding region that are located in the same one pixel disposition region are arranged in a second direction, wherein the first direction and the second direction are parallel to the plane on which the display panel is located; and a length of the first light-emitting element in the first direction is equal to a length of the second light-emitting element in the first direction; a length of the first light-emitting element in the second direction is equal to a length of the second light-emitting element in the second direction.

20. A display device, comprising a display panel, wherein the display panel comprises a first array substrate and a plurality of light-emitting elements located on one side of the first array substrate, wherein a light-emitting element of the plurality of light-emitting elements comprises a first binding electrode and a second binding electrode;
wherein the first array substrate comprises a plurality of pixel disposition regions corresponding to the plurality of light-emitting elements respectively, wherein a pixel disposition region of the plurality of pixel disposition regions comprises at least one of a first pad or a second pad; the first binding electrode is electrically connected to the first pad; the second binding electrode is electrically connected to the second pad; and
wherein at least one of the following is satisfied: an area of a projection of the first pad on a plane on which the display panel is located is greater than or equal to N times an area of a projection of the first binding electrode on the plane on which the display panel is located, or an area of a projection of the second pad on the plane on which the display panel is located is greater than or equal to N times an area of a projection of the second binding electrode on the plane on which the display panel is located, wherein N≥2.
